(19) United States
(12) Patent Application Publication
(10) Pub. No.: US 2023/0360897 A1
(43) Pub. Date: Nov. 9, 2023

(54) SPUTTERING TARGET-BACKING PLATE ASSEMBLY, MANUFACTURING METHOD THEREFOR, AND RECOVERY METHOD FOR SPUTTERING TARGET

(71) Applicant: FURUYA METAL CO., LTD., Tokyo (JP)

(72) Inventors: Tomohiro Maruko, Tokyo (JP); Yu Suzuki, Tokyo (JP); Shohei Otomo, Tokyo (JP); Hironobu Nakamura, Tokyo (JP)

(73) Assignee: FURUYA METAL CO., LTD., Tokyo (JP)

(21) Appl. No.: 18/246,360

(22) PCT Filed: Sep. 14, 2021
(86) PCT No.: PCT/JP2021/033674

§ 371 Date: Mar. 23, 2023

(30) Foreign Application Priority Data
Sep. 30, 2020 (JP) 2020-165872
Feb. 18, 2021 (JP) 2021-024010

(51) Int. Cl. H01J 37/34; C23C 14/34

(52) U.S. Cl. CPC H01J 37/3435; H01J 37/3426; C23C 14/3414

(57) ABSTRACT

A sputtering target-backing plate assembly comprising, a target has a thickness of 2.0 to 15.0 mm is joined to a backing plate, the backing plate has a recessed section having a depth of 0.5 to 5.0 mm on a plate surface, the target is fitted into the recessed section, and the assembly has a swaging structure in which an outer-peripheral-side surface of the target is clamped by a recessed section inner-peripheral-side surface of the backing plate.

### TECHNICAL FIELD

The present disclosure relates to a sputtering target-backing plate assembly suitable for setting in a sputtering equipment used in a process of manufacturing a hard disk drive (HDD), a semiconductor, or the like, a manufacturing method therefor, and a recovery method for a sputtering target.

### BACKGROUND ART

A sputtering target-backing plate assembly in which a sputtering target is joined to a member called a backing plate is generally used to set the sputtering target in a sputtering equipment used in a process of manufacturing an HDD, a semiconductor, or the like. By fixing the backing plate in the sputtering target-backing plate assembly, the sputtering target is installed in the sputtering equipment through the backing plate.

Since the backing plate is a member supporting the sputtering target and is a member for cooling to control an increase in temperature of the sputtering target due to exposure to plasma, the backing plate is formed of a material having a high thermal conductivity such as a copper-based material or an aluminum-based material. In addition, adhesion between the sputtering target and the backing plate needs to be maintained for thermal conduction.

The sputtering target and the backing plate are joined by a joining method generally called bonding, in which a material having a low melting point and a low vapor pressure in vacuum such as indium or tin is used as an insert material, or a joining method using a resin having a conductivity.

However, when the temperature of the sputtering target is higher than the melting point of indium, tin, or the like used as the insert material, indium or tin may be evaporated and mixed as an impurity into a formed film, which is a fatal problem in applications requiring a high purity.

There are technologies in which pressure is applied to the sputtering target and the backing plate in directions opposite to each other without using a low melting point metal serving as the insert material, and diffusion joining is performed over time with the temperature increased, in order to solve the problem of the bonding (for example, see Patent Literatures 1 to 3).

In Patent Literature 1, on a sputtering target made of tantalum having a yield strength of 15 to 20 kgf/mm², it is disclosed that the direction of warpage of the sputtering target caused by thermal expansion and contraction is controlled by using a backing plate material that have a yield strength same as or higher than that of the sputtering target and also using diffusion-bonded assembly between the sputtering target and the backing plate.

Patent Literature 2 discloses that a target material having a melting point of 1000° C. or higher, one or more insert materials selected from a metal or alloy having a melting point lower than the melting point of the target material, and the backing plate are subjected to solid-phase diffusion joining to obtain a high adhesion and high joining strength with a 100% joining rate.

Patent Literature 3 discloses a method for producing an assembly by forming a sandwich structure in which the entire surface of the sputtering target is embedded, applying thermal compression to 400 to 600° C. by hot isostatic pressing (HIP) or uniaxial hot pressing (UHP) to perform diffusion joining, and then cutting the sputtering target and the backing plate.

### CITATION LIST

### Patent Literature

Patent Literature 1: JP 2015-183258 A
Patent Literature 2: JP H06-108246 A
Patent Literature 3: JP 2014-511436 A

### SUMMARY OF INVENTION

### Technical Problem

However, the sputtering target formed of a material having a low flexural strength as in the invention described in Patent Literature 1, when a difference in linear expansion coefficient between the sputtering target and the backing plate is large, may be damaged during a period of diffusion joining at a high temperature and subsequent cooling and thermal contraction. Therefore, the diffusion joining is performed at a low temperature in some cases, but in these cases, the diffusion joining is not made properly, or a sufficient strength cannot be obtained.

In addition, even when the sputtering target and the backing plate having a large difference in linear expansion coefficient are subjected only to diffusion joining by heating and pressurization, repeatedly raising and lowering temperature during use of the sputtering target may cause accumulated fatigue on a joining interface, and as a result, fracture and peeling may occur.

In addition, in the invention described in Patent Literature 2, when the temperature is raised to the melting point of the insert material during use of the sputtering target, the insert material may be melted, and the sputtering target may be peeled off. Such a tendency is likely to occur in semiconductor manufacturing in which a large target is used and a high purity is required.

In addition, in order to reduce the difference in linear expansion coefficient, means for reducing stress, such as putting an insert material having a linear expansion coefficient near the middle between those of the sputtering target and the backing plate, may be used, but the problem that the insert material evaporates and impurities are mixed is not solved as in a case of metal joining by bonding or joining using a conductive resin.

In the invention described in Patent Literature 3, since diffusion joining process is performed until formation of strong diffusion joining between the sputtering target and the backing plate, cracking of the sputtering target may occur in the diffusion joining process for the sputtering target, due to the large difference in linear expansion coefficient between the sputtering target and the backing plate, depending on the material of the sputtering target.

Therefore, an object of the present disclosure is to provide a sputtering target-backing plate assembly, a manufacturing method therefor, and a recovery method for a sputtering target, which can suppress damage to and peeling of the sputtering target, can suppress contamination due to evaporation of impurities, and can facilitate peeling and recovery of a target material with suppression of loss of an expensive material used as the target material even when the sputtering target having a low flexural strength is used or when a difference in linear expansion coefficient between the sputtering target and a backing plate is large.

### Solution to Problem

As a result of intensive studies, the present inventors have found that the above problems can be solved by performing swaging and diffusion joining, and have completed the present invention. That is, a sputtering target-backing plate assembly according to the present invention is a sputtering target-backing plate assembly in which a sputtering target having a thickness of 2.0 to 15.0 mm is joined to a backing plate, the backing plate having a recessed section having a depth of 0.5 to 5.0 mm on a plate surface, the sputtering target being fitted into the recessed section, and the sputtering target-backing plate assembly having a swaging structure in which an outer-peripheral-side surface of the sputtering target is clamped by a recessed section inner-peripheral-side surface of the backing plate.

In the sputtering target-backing plate assembly according to the present invention, it is preferable that the outer-peripheral-side surface of the sputtering target has an uneven portion, the recessed section inner-peripheral-side surface of the backing plate has an uneven portion, and the uneven portion of the outer-peripheral-side surface and the uneven portion of the recessed section inner-peripheral-side surface are fitted to each other. It is possible to improve a strength of joining by swaging in a thickness direction of the sputtering target and the backing plate in addition to improving the strength of joining by swaging between the outer-peripheral-side surface of the sputtering target and the recessed section inner-peripheral-side surface of the backing plate, and as a result, the joining strength during use of the sputtering target can be maintained, and the thermal conduction can be favorably maintained.

In the sputtering target-backing plate assembly according to the present invention, a recessed section opening surface of the recessed section of the backing plate is preferably smaller than a recessed section bottom surface of the recessed section. It is possible to improve a strength of joining by swaging in a thickness direction of the sputtering target and the backing plate in addition to improving the strength of joining by swaging between the outer-peripheral-side surface of the sputtering target and the recessed section inner-peripheral-side surface of the backing plate, and as a result, the joining strength during use of the sputtering target can be maintained, and the thermal conduction can be favorably maintained.

In the sputtering target-backing plate assembly according to the present invention, a bottom surface of the sputtering target is preferably larger than the recessed section opening surface of the recessed section of the backing plate. By improving the strength of joining by swaging between the outer-peripheral-side surface of the sputtering target and the recessed section inner-peripheral-side surface of the backing plate, the joining strength during use of the sputtering target can be maintained, and thermal conduction can be favorably maintained.

In the sputtering target-backing plate assembly according to the present invention, a linear expansion coefficient of the backing plate is preferably larger than a linear expansion coefficient of the sputtering target, at 200 to 500° C. As the backing plate is expanded during a period of heating, the recessed section of the backing plate can be filled with the sputtering target, and the backing plate is contracted during a period of cooling, so that the outer-peripheral-side surface of the sputtering target can be swaged with the recessed section inner-peripheral-side surface of the backing plate to form the sputtering target-backing plate assembly.

In the sputtering target-backing plate assembly according to the present invention, an intermediate layer having a thickness of 2.5 mm or less is provided on an interface between the sputtering target and the backing plate, and the intermediate layer is preferably composed of a plate material or powder formed of at least one metal of Ni, Cr, Al, or Cu or an alloy containing at least one of Ni, Cr, Al, or Cu, or a combination of the plate material and the powder. As the intermediate layer is provided, the joining strength between the bottom surface of the sputtering target and the recessed section bottom surface of the backing plate can be improved, and the adhesion can be improved to maintain favorable thermal conduction. In addition, since the intermediate layer is provided in the recessed section of the backing plate, the intermediate layer is covered with the sputtering target, so that it is possible to suppress the material of the intermediate layer from being evaporated and becoming impurities and adhering to a substrate.

In the sputtering target-backing plate assembly according to the present invention, the intermediate layer having a thickness of 10 μm or less is provided on the interface between the sputtering target and the backing plate, and the intermediate layer is preferably composed of a thin film formed of at least one metal of Ni, Cr, Al, or Cu or an alloy containing at least one metal of Ni, Cr, Al, or Cu. As the intermediate layer is provided, the joining strength between the bottom surface of the sputtering target and the recessed section bottom surface of the backing plate can be improved, and the adhesion can be improved to maintain favorable thermal conduction. In addition, since the intermediate layer is provided in the recessed section of the backing plate, the intermediate layer is covered with the sputtering target, so that it is possible to keep the material of the intermediate layer from being evaporated and becoming impurities and adhering to a substrate.

In the sputtering target-backing plate assembly according to the present invention, an intermediate layer having a thickness of 1.0 mm or less is provided on an interface between the sputtering target and the backing plate, and the intermediate layer is preferably composed of a plate material or powder formed of at least one metal of In or Zn or an alloy containing at least one of In or Zn, or a combination of the plate material and the powder. As the intermediate layer is provided, the joining strength between the bottom surface of the sputtering target and the recessed section bottom surface of the backing plate can be improved, and the adhesion can be improved to maintain favorable thermal conduction. In addition, since the intermediate layer is provided in the recessed section of the backing plate, the intermediate layer is covered with the sputtering target, so that it is possible to keep the material of the intermediate layer from being evaporated and becoming impurities and adhering to a substrate.

In the sputtering target-backing plate assembly according to the present invention, two or more intermediate layers are provided on an interface between the sputtering target and the backing plate, and it is preferable that the intermediate layer is composed of a plate material having a thickness of 2.5 mm or less or powder and formed of at least one metal of Ni, Cr, Al, or Cu or an alloy containing at least one of Ni, Cr, Al, or Cu, or a combination of the plate material and the powder, is composed of a thin film having a thickness of 10 μm or less and formed of at least one metal of Ni, Cr, Al, or Cu or an alloy containing at least one of Ni, Cr, Al, or Cu, or is composed of a plate material having a thickness of 1.0 mm or less or powder and formed of at least one metal of In or Zn or an alloy containing at least one of In or Zn, or a combination of the plate material and the powder. As two or more intermediate layers are provided, the joining strength between the bottom surface of the sputtering target and the recessed section bottom surface of the backing plate can be improved, and the adhesion can be improved to maintain favorable thermal conduction. In addition, since the intermediate layer is provided in the recessed section of the backing plate, the intermediate layer is covered with the sputtering target, so that it is possible to keep the material of the intermediate layer from being evaporated and becoming impurities and adhering to a substrate.

In the sputtering target-backing plate assembly according to the present invention, a material of the sputtering target is preferably an Al—Sc alloy, Ru, Ru alloy, Ir, or Ir alloy. Even with a material having a high melting point of 1000° C. or higher, it is possible to improve the joining strength between the sputtering target and the backing plate while suppressing warpage and cracking of the sputtering target.

In the sputtering target-backing plate assembly according to the present invention, a material of the sputtering target is preferably a Li-based oxide, a Co-based oxide, a Ti-based oxide, or an Mg-based oxide. Even with a material having a high melting point of 1000° C. or higher, it is possible to improve the joining strength between the sputtering target and the backing plate while suppressing warpage and cracking of the sputtering target.

In the sputtering target-backing plate assembly according to the present invention, it is preferable that a material of the backing plate is Al, an Al alloy, Cu, a Cu alloy, Fe, or an Fe alloy, and the linear expansion coefficient of the backing plate is 30.0×10⁻⁶/° C. or less. As the backing plate having a favorable thermal conductivity is used, the backing plate is expanded during a period of heating, so that the sputtering target can be inserted into the recessed section of the backing plate, and the backing plate is contracted at the time of cooling, and therefore the outer-peripheral-side surface of the sputtering target can be swaged with the recessed section inner-peripheral-side surface of the backing plate to form the assembly.

The sputtering target-backing plate assembly according to the present invention encompasses a form in which a flexural strength of the sputtering target is 500 MPa or less. The sputtering target-backing plate assembly can also be applied to a sputtering target having a low flexural strength.

In the sputtering target-backing plate assembly according to the present invention, a planar shape of the recessed section of the backing plate is preferably a circular shape or a rectangular shape including a square shape, and a relationship between a diameter or side length of the recessed section of the backing plate and a diameter or side length of the sputtering target preferably satisfies (Expression 1) to (Expression 5):

D_{TG}>D_{BP} (Expression 1)

D_{BP}=D_{TG}−ΔD×C (Expression 2)

ΔD=D_{BP}×ΔT×CTE_{BP}−D_{TG}×ΔT×CTE_{TG} (Expression 3)

D_{TG}−ΔD×4.0≤D_{BP}≤D_{TG}−ΔD×0.5 (Expression 4)

CTE_{BP}>CTE_{TG} (Expression 5)
where D_{BP}, D_{TG}, ΔD, C, T, ΔT, CTE_{BP}, and CTE_{TG} mean the following:
D_{BP}: the diameter or side length (mm) of the recessed section of the backing plate at room temperature
D_{TG}: the diameter or side length (mm) of the sputtering target at the room temperature
T: a temperature (° C.) at which the backing plate is thermally expanded to fit the sputtering target (where T>the room temperature)
ΔT: T—the room temperature (° C.)
CTE_{BP}: the linear expansion coefficient (1/° C.) of the backing plate at the temperature T
CTE_{TG}: the linear expansion coefficient (1/° C.) of the sputtering target at the temperature T
C: a coefficient (where C=0.5 to 4.0)
ΔD: a difference (mm) in thermal expansion amount between the backing plate and the sputtering target under the condition of rising a temperature from the room temperature to the temperature T

While joining the sputtering target to the backing plate by swaging between the outer-peripheral-side surface of the sputtering target and the recessed section inner-peripheral-side surface of the backing plate, cracking and warpage of the sputtering target can be suppressed.

In the sputtering target-backing plate assembly according to the present invention, a planar shape of the recessed section of the backing plate is preferably a circular shape or a rectangular shape including a square shape, and a relationship between a diameter or side length of the recessed section of the backing plate and a diameter or side length of the sputtering target preferably satisfies (Expression 6) to (Expression 10):

D_{TG}>D_{BP} (Expression 6)

D_{BP}=D_{TG}−ΔD×C (Expression 7)

ΔD=D_{BP}×ΔT×CTE_{BP}−D_{TG}×ΔT₁×CT₁E_{TG} (Expression 8)

D_{TG}−ΔD×4.0≤D_{BP}≤D_{TG}−ΔD×0.5 (Expression 9)

CTE_{BP}>CT₁E_{TG} (Expression 10)
where D_{BP}, D_{TG}, ΔD, C, T, ΔT, T₁, ΔT₁, CTE_{BP}, and CT₁E_{TG} mean the following:
D_{BP}: the diameter or side length (mm) of the recessed section of the backing plate at room temperature
D_{TG}: the diameter or side length (mm) of the sputtering target at the room temperature
T: a temperature (° C.) of the backing plate at which the backing plate is thermally expanded to fit the sputtering target (where T>the room temperature and T>T₁)
ΔT: T—the room temperature (° C.)
T₁: a temperature (° C.) of the sputtering target at which the backing plate is thermally expanded to fit the sputtering target (where T₁>the room temperature and T>T₁)
ΔT₁: T₁—the room temperature (° C.)
CTE_{BP}: the linear expansion coefficient (1/° C.) of the backing plate at the temperature T
CT₁E_{TG}: the linear expansion coefficient (1/° C.) of the sputtering target at the temperature T₁
C: a coefficient (where C=0.5 to 4.0)
ΔD: a difference (mm) between a thermal expansion amount of the backing plate under the condition of rising a temperature from the room temperature to the temperature T and a thermal expansion amount of the sputtering target under the condition of rising a temperature from the room temperature to the temperature T₁

While joining the sputtering target to the backing plate by swaging between the outer-peripheral-side surface of the sputtering target and the recessed section inner-peripheral-side surface of the backing plate, cracking and warpage of the sputtering target can be suppressed.

In the sputtering target-backing plate assembly according to the present invention, it is preferable that the sputtering target is fitted into the backing plate such that the plate surface of the backing plate is exposed to an entire periphery of a target surface of the sputtering target. Even after the sputtering target and the backing plate are joined by swaging between the outer-peripheral-side surface of the sputtering target and the recessed section inner-peripheral-side surface of the backing plate, the sputtering target-backing plate assembly can be easily set in a sputtering equipment by using the exposed portion of the plate surface.

In the sputtering target-backing plate assembly according to the present invention, the target surface of the sputtering target preferably protrudes from the plate surface. While joining the sputtering target to the backing plate by swaging between the outer-peripheral-side surface of the sputtering target and the recessed section inner-peripheral-side surface of the backing plate, cracking and warpage of the sputtering target can be suppressed. Further, in manufacturing, only the sputtering target surface can be pressed to be joined.

A manufacturing method for a sputtering target-backing plate assembly according to the present invention includes: a step 1 of preparing a sputtering target having a thickness of 2.0 to 15.0 mm and a backing plate; a step 2 of forming a recessed section having a depth of 0.5 to 5.0 mm in a plate surface of the backing plate; a step 3 of heating the backing plate to thermally expand the recessed section; a step 4 of fitting the sputtering target into the thermally expanded recessed section; and a step 5 of cooling the backing plate to form a swaging structure in which the outer-peripheral-side surface of the sputtering target is clamped by the recessed section inner-peripheral-side surface of the backing plate. The sputtering target-backing plate assembly can be manufactured by swaging between the outer-peripheral-side surface of the sputtering target and the recessed section inner-peripheral-side surface of the backing plate.

The manufacturing method for a sputtering target-backing plate assembly according to the present invention preferably further includes, between the step 2 and the step 3 or between the step 3 and the step 4, a step 6 of filling or coating the recessed section with a material of an intermediate layer. It is possible to manufacture the sputtering target-backing plate assembly in which the joining strength between the bottom surface of the sputtering target and the recessed section bottom surface of the backing plate is improved, adhesion is improved, and favorable thermal conduction is maintained.

The manufacturing method for a sputtering target-backing plate assembly according to the present invention preferably further includes, between the step 4 and the step 5, a step 7 of pressing the sputtering target to diffuse a bottom surface of the sputtering target and a bottom surface of the recessed section of the backing plate. By diffusing the bottom surface of the sputtering target and the recessed section bottom surface of the backing plate, the bottom surface of the sputtering target and the recessed section bottom surface of the backing plate are entirely joined to each other, so that adhesion is improved and thermal conduction can be efficiently performed.

In the manufacturing method for a sputtering target-backing plate assembly according to the present invention, it is preferable that at least the step 3, the step 4, and the step 5 are performed by using at least one of a hot press (HP) sintering method, a hot isostatic pressing (HIP) sintering method, a spark plasma sintering (SPS) method, or a heating method using a hot plate. The sputtering target and the backing plate are more reliablyjoined to each other, and thus, the adhesion is improved, so that heat conduction can be efficiently performed.

In the manufacturing method for a sputtering target-backing plate assembly according to the present invention, it is preferable that the step 7 is performed by using at least one of a hot press (HP) sintering method, a hot isostatic pressing (HIP) sintering method, or a spark plasma sintering (SPS) method. By diffusing the bottom surface of the sputtering target and the recessed section bottom surface of the backing plate, the bottom surface of the sputtering target and the recessed section bottom surface of the backing plate are entirely joined to each other, so that adhesion is improved and thermal conduction can be efficiently performed.

In the manufacturing method for a sputtering target-backing plate assembly according to the present invention, it is preferable that, in the step 7, a reduced-pressure atmosphere of 10 Pa or less or an atmosphere having an oxygen concentration of 1000 ppm or less is set, a heating temperature is set to 100 to 1000° C., and a pressing force is set to a range of 0 Pa or more and 80 MPa or less. An oxygen content of the sputtering target can be reduced.

In the manufacturing method for a sputtering target-backing plate assembly according to the present invention, it is preferable that, after the step 5, a pair of a step of pressing or heating and pressing and a step of cooling is performed once or repeatedly twice or more. The joining strength between the bottom surface of the sputtering target and the recessed section bottom surface of the backing plate can be further improved while suppressing warpage of the sputtering target, and thus, the adhesion can be improved, so that heat conduction can be efficiently performed.

A recovery method for a sputtering target according to the present invention includes: a step A of heating the sputtering target-backing plate assembly according to the present invention to thermally expand the recessed section opening surface of the backing plate until making the recessed section opening surface larger than the bottom surface of the sputtering target; and a step B of detaching the sputtering target from the backing plate to recover the sputtering target from the sputtering target-backing plate assembly.

### Advantageous Effects of Invention

The present disclosure can provide a sputtering target-backing plate assembly, a manufacturing method therefor, and a recovery method for a sputtering target, which can suppress damage to and peeling of the sputtering target, can suppress contamination due to evaporation of impurities, and can facilitate peeling and recovery of a target material with suppression of loss of an expensive material used as the target material even when the sputtering target having a low flexural strength is used or when a difference in linear expansion coefficient between the sputtering target and a backing plate is large.

### BRIEF DESCRIPTION OF DRAWINGS

FIG. 1 is a schematic plan view of a disk-shaped sputtering target-backing plate assembly according to the present embodiment.

FIG. 2 is a schematic cross-sectional view taken along line A-A of a first example.

FIG. 3 is a schematic plan view of a rectangular plate-shaped sputtering target-backing plate assembly according to the present embodiment.

FIG. 4 is a schematic cross-sectional view taken along line A-A of a second example.

FIG. 5 is a schematic cross-sectional view taken along line A-A of a third example.

FIG. 6 is a schematic cross-sectional view taken along line A-A of a fourth example.

FIG. 7 is a schematic cross-sectional view taken along line A-A of a fifth example.

FIG. 8 is a schematic cross-sectional view taken along line A-A of a sixth example.

FIG. 9 is a schematic cross-sectional view taken along line A-A of a seventh example.

FIG. 10 is a schematic cross-sectional view taken along line A-A of an eighth example.

FIG. 11 is a first schematic process view for explaining a process of manufacturing the sputtering target-backing plate assembly according to the present embodiment.

FIG. 12 is a second schematic process view for explaining a process of manufacturing the sputtering target-backing plate assembly according to the present embodiment.

FIG. 13 is a third schematic process view for explaining a process of manufacturing the sputtering target-backing plate assembly according to the present embodiment.

FIG. 14 is a fourth schematic process view for explaining a process of manufacturing the sputtering target-backing plate assembly according to the present embodiment.

FIG. 15 is a schematic process view illustrating a part of a process of a manufacturing method of the second example.

FIG. 16 is a schematic process view illustrating a part of a process of a manufacturing method of the third example.

FIG. 17 is a schematic process view illustrating a part of a process of a manufacturing method of the fourth example.

FIG. 18 is a schematic process view illustrating a part of a process of a manufacturing method of the fifth example.

FIG. 19 is a schematic process view illustrating a part of a process of a manufacturing method of the sixth example.

FIG. 20 is an image showing a swaged and diffused portion in Example 1.

FIG. 21 is an image showing a swaged and diffused portion in Example 2.

FIG. 22 is an image showing a joining result in Comparative Example 1.

FIG. 23 is an image showing a joining result in Comparative Example 2.

FIG. 24 is an image showing a joining result in Comparative Example 3.

FIG. 25 is an image showing a joining result in Comparative Example 4.

### DESCRIPTION OF EMBODIMENTS

Hereinafter, the present invention will be described in detail with reference to embodiments, but the present invention is not construed as being limited to these embodiments. The embodiments may be variously modified as long as the effect of the present invention is exhibited. In the drawings, in each assembly, a portion having the same name is denoted by the same reference sign regardless of the shape or geometry.

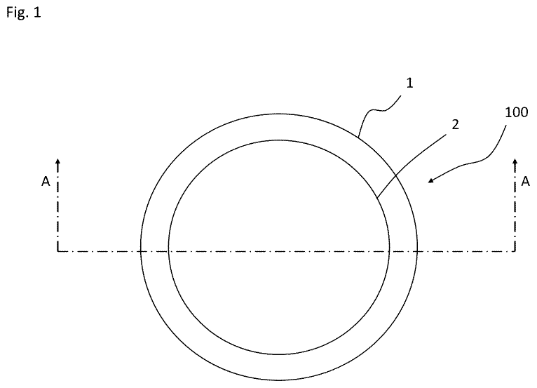

A sputtering target-backing plate assembly according to the present embodiment will be described with reference to FIGS. 1 and 2. A sputtering target-backing plate assembly 100 according to the present embodiment is a sputtering target-backing plate assembly in which a disk-shaped sputtering target 2 having a thickness of 2.0 to 15.0 mm is joined to a disk-shaped backing plate 1, the backing plate 1 having a recessed section 4 having a depth of 0.5 to 5.0 mm on a plate surface 3, the sputtering target 2 being fitted into the recessed section 4, and the sputtering target-backing plate assembly 100 having a swaging structure in which an outer-peripheral-side surface 5 of the sputtering target 2 is clamped by a recessed section inner-peripheral-side surface 6 of the backing plate 1. Here, the swaging structure refers to a structure in which the recessed section inner-peripheral-side surface 6 presses the outer-peripheral-side surface 5. This structure produces at least static friction between the outer-peripheral-side surface 5 and the recessed section inner-peripheral-side surface 6, and the sputtering target 2 is fixed to the backing plate 1. For example, in the sputtering target-backing plate assembly 100 according to the present embodiment, a bottom surface 9 of the sputtering target 2 is preferably larger than a recessed section opening surface 21 of the recessed section 4 of the backing plate 1, so that the sputtering target-backing plate assembly 100 can have the swaging structure. The recessed section opening surface 21 is an extension surface of a surface of the backing plate 1 being contiguous to the plate surface 3, and is an imaginary surface that covers an opening of the recessed section 4. Here, it is preferable that the bottom surface 9 of the sputtering target 2 and the recessed section opening surface 21 of the recessed section 4 of the backing plate 1 have similar shapes within the range of processing accuracy.

The recessed section 4 has a recessed section bottom surface 7 and the recessed section inner-peripheral-side surface 6. The recessed section bottom surface 7 is preferably a flat surface parallel to the plate surface 3 or a back surface of the backing plate 1. When the depth of the recessed section 4 is less than 0.5 mm, with the sputtering target 2 fitted into the recessed section 4 and the outer-peripheral-side surface 5 of the sputtering target 2 joined to the recessed section inner-peripheral-side surface 6 of the backing plate 1 by swaging, the joining strength is insufficient, so that the sputtering target 2 is likely to be peeled from the backing plate 1. On the other hand, when the depth of the recessed section 4 is more than 5 mm, with the outer-peripheral-side surface 5 of the sputtering target 2 joined to the recessed section inner-peripheral-side surface 6 of the backing plate 1 by swaging, a pressing force from the recessed section inner-peripheral-side surface 6 is excessively strong, so that the sputtering target is likely to be cracked or warped. The plate surface 3 and the back surface of the backing plate 1 may have unevenness or inclinations within a range in which charge concentration does not occur, but the plate surface 3 and the back surface are preferably flat surfaces and are parallel to each other.

The sputtering target 2 has a thickness of 2.0 to 15.0 mm. When the thickness of the sputtering target 2 is less than 2.0 mm, a surface (also referred to as a sputtering surface) of the sputtering target 2 may be lower than the plate surface 3 of the backing plate 1, and when the thickness is more than 15.0 mm, the joining strength between the backing plate 1 and the sputtering target 2 may be insufficient. The plate surface 3 and the sputtering surface are preferably parallel to each other. The backing plate 1 has a thickness of, for example, 3.0 to 40.0 mm.

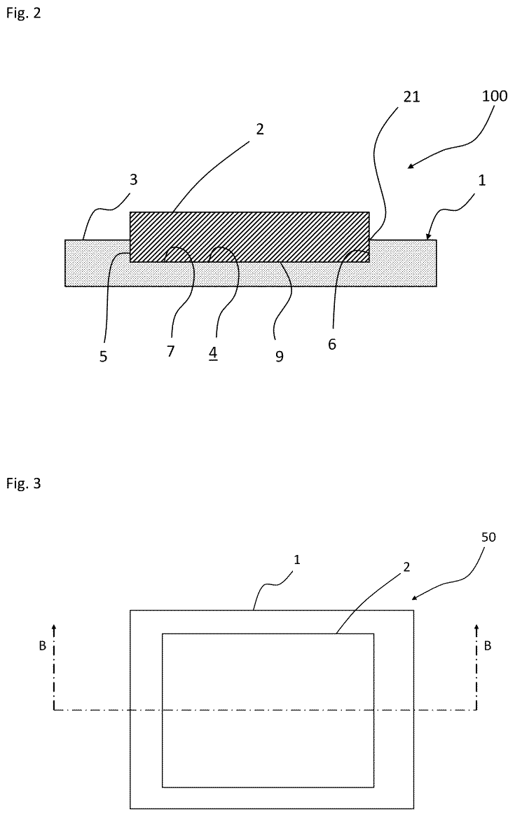

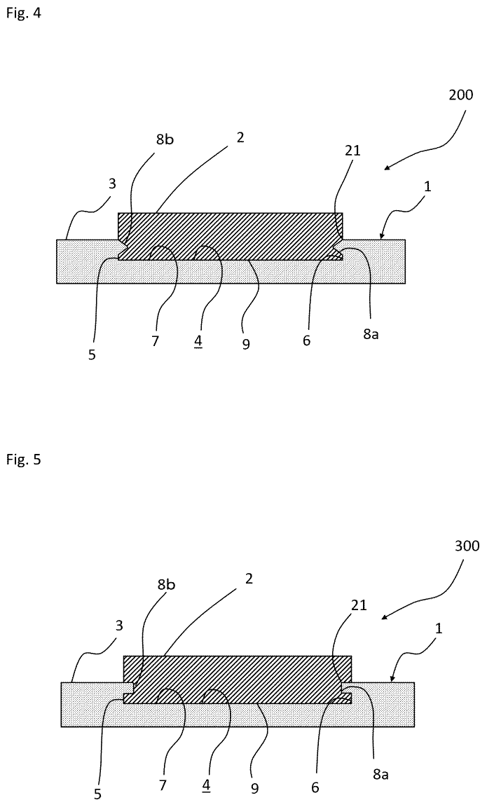

In FIGS. 1 and 2, the disk-shaped sputtering target 2 is joined to the disk-shaped backing plate 1, but as illustrated in FIG. 3, a rectangular sputtering target 2 may be joined to a rectangular backing plate 1. The B-B cross section has the same shape as that of the A-A cross section illustrated in FIG. 2. The rectangular shape includes a square shape. In the present embodiment, it is preferable that a plate-shaped sputtering target having a disk shape including an elliptical shape, a rectangular shape including a square shape, a polygonal shape, or the like is formed and then joined to a backing plate.

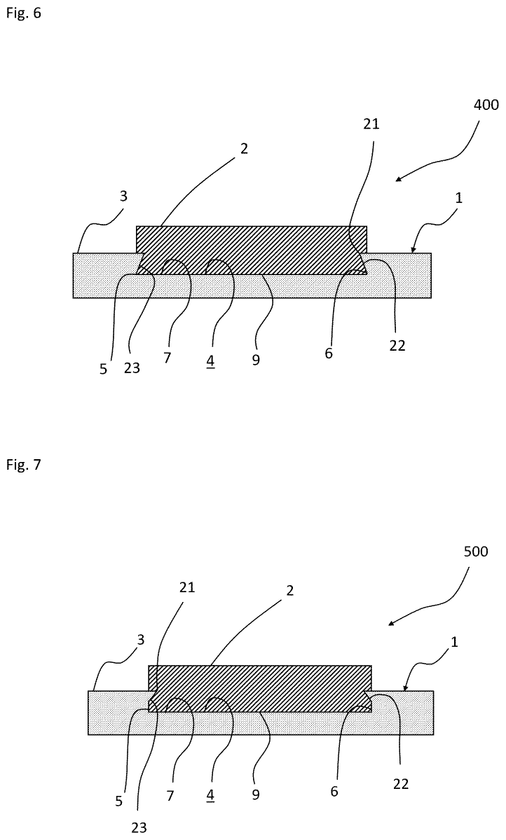

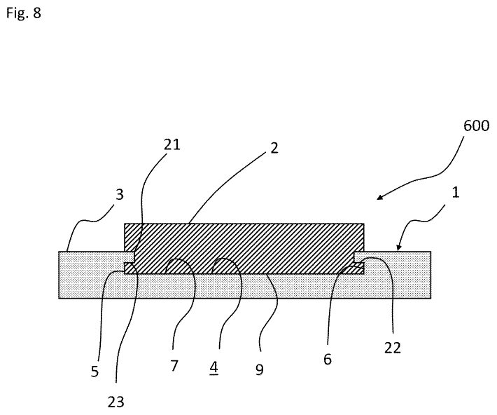

As illustrated in FIG. 4 or 5, in sputtering target-backing plate assemblies 200 and 300 according to the present embodiment, it is preferable that the outer-peripheral-side surface 5 of the sputtering target 2 has an uneven portion 8a, the recessed section inner-peripheral-side surface 6 of the backing plate 1 has an uneven portion 8b, and the uneven portion 8a of the outer-peripheral-side surface 5 and the uneven portion 8b of the recessed section inner-peripheral-side surface 6 are fitted to each other. It is possible to improve the strength of joining by swaging in a thickness direction of the sputtering target 2 and the backing plate 1 in addition to improving the strength of joining by swaging between the outer-peripheral-side surface 5 of the sputtering target 2 and the recessed section inner-peripheral-side surface 6 of the backing plate 1. As a result, the joining strength during use of the sputtering target 2 can be maintained, and thermal conduction can be favorably maintained. In addition, when the strengths of joining by swaging in a peripheral direction and thickness direction of the outer-peripheral-side surface of the sputtering target 2 and in a peripheral direction and thickness direction of the recessed section inner-peripheral-side surface of the backing plate are sufficient, the joining strength between the bottom surface 9 of the sputtering target and the recessed section bottom surface 7 of the backing plate can be intentionally weakened, so that the sputtering target can be easily peeled and recovered from the backing plate after using the sputtering target.

As illustrated in FIG. 4, when a cross-sectional shape of the uneven portion 8a of the outer-peripheral-side surface 5 is a recessed triangle, a cross-sectional shape of the uneven portion 8b of the recessed section inner-peripheral-side surface 6 is a protruding triangle. The recessed triangle and the protruding triangle preferably have a relationship in which surfaces thereof are in contact with each other. As illustrated in FIG. 5, when a cross-sectional shape of the uneven portion 8a of the outer-peripheral-side surface 5 is a recessed quadrangle, a cross-sectional shape of the uneven portion 8b of the recessed section inner-peripheral-side surface 6 is a protruding quadrangle. The recessed quadrangle and the protruding quadrangle preferably have a relationship in which surfaces thereof are in contact with each other. In addition to the above form, a recessed semicircular shape and a protruding semicircular shape, or a recessed semi-elliptical shape and a protruding semi-elliptical shape may be used. In addition, a relationship between the recessed shape and the protruding shape may be inverted between a sputtering target side and a backing plate side. Further, the uneven portion 8a of the outer-peripheral-side surface 5 and the uneven portion 8b of the recessed section inner-peripheral-side surface 6 may be provided over the entire periphery in each peripheral direction or may be provided at a part in each peripheral direction. Further, the uneven portion 8a of the outer-peripheral-side surface 5 and the uneven portion 8b of the recessed section inner-peripheral-side surface 6 may be provided in two or more rows along a depth direction of the recessed section 4.

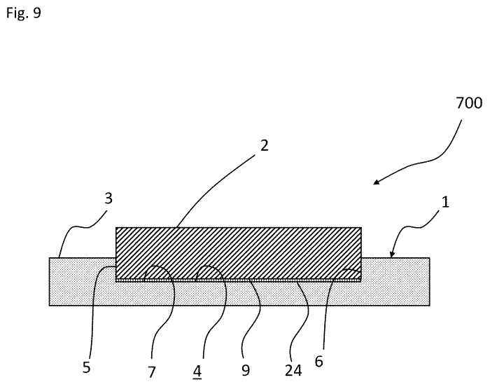

As illustrated in FIGS. 6 to 8, in sputtering target-backing plate assemblies 400, 500, and 600 according to the present embodiment, the recessed section opening surface 21 of the recessed section 4 of the backing plate 1 is preferably smaller than the recessed section bottom surface 7 of the recessed section 4. It is possible to improve the strength of joining by swaging in a thickness direction of the sputtering target 2 and the backing plate 1 in addition to improving the strength of joining by swaging between the outer-peripheral-side surface 5 of the sputtering target 2 and the recessed section inner-peripheral-side surface 6 of the backing plate 1. As a result, the joining strength during use of the sputtering target 2 can be maintained, and thermal conduction can be favorably maintained. In addition, when the strength of joining by swaging between the outer-peripheral-side surface 5 of the sputtering target 2 and the recessed section inner-peripheral-side surface 6 of the backing plate 1 is sufficient, the joining strength between the bottom surface 9 of the sputtering target 2 and the recessed section bottom surface 7 of the backing plate 1 can be intentionally weakened, so that the sputtering target 2 can be easily peeled and recovered from the backing plate 1 after using the sputtering target 2.

As illustrated in FIG. 6, when the cross-sectional shape of the outer-peripheral-side surface 5 has a triangular recessed section 22, the cross-sectional shape of the recessed section inner-peripheral-side surface 6 has a triangular protruding section 23, and the protruding section 23 makes the recessed section opening surface 21 of the recessed section 4 smaller than the recessed section bottom surface 7. The recessed section 22 and the protruding section 23 preferably have a relationship in which surfaces thereof are in contact with each other. FIG. 6 illustrates a form in which the cross-sectional shape of the recessed section inner-peripheral-side surface 6 is entirely inclined in the depth direction of the recessed section 4 by the protruding section 23. FIG. 7 illustrates, as a modification of FIG. 6, a form in which the cross-sectional shape of the recessed section inner-peripheral-side surface 6 is partially inclined in the depth direction of the recessed section 4 by the protruding section 23. Further, as illustrated in FIG. 8, when the cross-sectional shape of the outer-peripheral-side surface 5 has a quadrangular recessed section 22, the cross-sectional shape of the recessed section inner-peripheral-side surface 6 has a quadrangular protruding section 23, and the protruding section 23 makes the recessed section opening surface 21 of the recessed section 4 smaller than the recessed section bottom surface 7. The recessed section 22 and the protruding section 23 preferably have a relationship in which surfaces thereof are in contact with each other. The shapes of the recessed section 22 and the protruding section 23 may be variously changed as long as the recessed section opening surface 21 is smaller than the recessed section bottom surface 7. In addition, a relationship between the recessed shape and the protruding shape may be inverted between a sputtering target side and a backing plate side. Further, the recessed section 22 and the protruding section 23 may be provided over the entire periphery in each peripheral direction or may be provided at a part in each peripheral direction.

In the sputtering target-backing plate assembly according to the present embodiment, a linear expansion coefficient of the backing plate 1 is preferably larger than a linear expansion coefficient of the sputtering target 2, at 200 to 500° C. In a condition where the linear expansion coefficient of the backing plate 1 is smaller than the linear expansion coefficient of the sputtering target 2, at 200 to 500° C., the sputtering target 2 has a larger range of expansion by heating and contraction by cooling than the backing plate 1, and it may be difficult to join the sputtering target 2 by swaging using the backing plate 1. In a condition where the linear expansion coefficient of the backing plate 1 is larger than the linear expansion coefficient of the sputtering target 2, the backing plate 1 has a larger expansion/contraction width than the sputtering target 2, the recessed section 4 of the backing plate 1 is expanded more than the sputtering target 2 in heating at the same temperature, and the recessed section 4 of the backing plate 1 is contracted more than the sputtering target 2 in cooling at the same temperature.

As illustrated in FIG. 9, in the sputtering target-backing plate assembly 700 according to the present embodiment, an intermediate layer 24 having a thickness of 2.5 mm or less is provided on an interface between the sputtering target 2 and the backing plate 1, and the intermediate layer 24 is preferably composed of a plate material or powder formed of at least one metal of Ni, Cr, Al, or Cu or an alloy containing at least one of Ni, Cr, Al, or Cu, or a combination of the plate material and the powder. Reducing the difference in linear expansion coefficient between the sputtering target 2 and the backing plate 1, by the intermediate layer 24, can further suppress damage to and warpage of the sputtering target 2 due to repeated expansion by heating and contraction by cooling. In addition, as the intermediate layer 24 is provided, the joining strength between the bottom surface 9 of the sputtering target 2 and the recessed section bottom surface 7 of the backing plate can be improved, and the adhesion can be improved to maintain favorable thermal conduction. In addition, since the intermediate layer 24 is provided in the recessed section 4 of the backing plate 1 and the intermediate layer 24 is covered with the sputtering target 2, it is possible to keep the material of the intermediate layer 24 from being evaporated and becoming impurities and adhering to a substrate. The reason why the elements of Ni, Cr, Al, and Cu are selected for the intermediate layer 24 is that the elements are suitable from the viewpoint of the adhesion, thermal conduction, and linear expansion coefficient. In an example where the intermediate layer 24 is a plate material, when the plate material is thicker than 2.5 mm, the recessed section 4 of the backing plate 1 needs to be deeper, and thus, the thickness of the backing plate 1 may need to be increased. In an example where the intermediate layer 24 is a powder layer, the intermediate layer 24 has a powder form by heating, a sintered powder form, or a form in which powder is melted by heating. The form in which the powder is melted by heating is similar to the form in which the intermediate layer 24 is the plate material. The intermediate layer 24 is preferably provided between the bottom surface 9 of the sputtering target 2 and the recessed section bottom surface 7 of the backing plate, but may be further provided on an interface between the outer-peripheral-side surface 5 of the sputtering target 2 and the recessed section inner-peripheral-side surface 6 of the recessed section 4 of the backing plate.

Similarly to the form illustrated in FIG. 9, in the sputtering target-backing plate assembly according to the present embodiment, the intermediate layer 24 having a thickness of 10 μm or less is provided on the interface between the sputtering target 2 and the backing plate 1, and the intermediate layer 24 is preferably a thin film formed of at least one metal of Ni, Cr, Al, or Cu or an alloy containing at least one metal of Ni, Cr, Al, or Cu. Reducing the difference in linear expansion coefficient between the sputtering target 2 and the backing plate 1, by the intermediate layer 24, can further suppress damage to and warpage of the sputtering target 2 due to repeated expansion by heating and contraction by cooling. Even in a condition where the film thickness of the intermediate layer 24 is larger than 10 μm, it only takes additional time to form the intermediate layer 24, and the effect as the intermediate layer 24 is not much different from that in a condition where the film thickness is 10 μm or less. In addition, as the intermediate layer 24 is provided, the joining strength between the bottom surface 9 of the sputtering target 2 and the recessed section bottom surface 7 of the backing plate can be improved, and the adhesion can be improved to maintain favorable thermal conduction. In addition, since the intermediate layer 24 is provided in the recessed section 4 of the backing plate 1 and the intermediate layer 24 is covered with the sputtering target 2, it is possible to keep the material of the intermediate layer 24 from being evaporated and becoming impurities and adhering to a substrate. The reason why the elements of Ni, Cr, Al, and Cu are selected for the intermediate layer 24 is that the elements are suitable from the viewpoint of the adhesion, thermal conduction, and linear expansion coefficient. The thin film is preferably a thin film obtained by sputtering, and is preferably formed on the recessed section bottom surface 7 of the backing plate. Further, the thin film may also be a foil having a thickness of 10 μm or less. The intermediate layer 24 is preferably provided between the bottom surface 9 of the sputtering target 2 and the recessed section bottom surface 7 of the backing plate, but may be further provided on an interface between the outer-peripheral-side surface 5 of the sputtering target 2 and the recessed section inner-peripheral-side surface 6 of the recessed section 4 of the backing plate.

Similarly to the form illustrated in FIG. 9, in the sputtering target-backing plate assembly according to the present embodiment, the intermediate layer 24 having a thickness of 1.0 mm or less is provided on the interface between the sputtering target 2 and the backing plate 1, and the intermediate layer 24 is preferably composed of a plate material or powder formed of at least one metal of In or Zn or an alloy containing at least one of In or Zn, or a combination of the plate material and the powder. Reducing the difference in linear expansion coefficient between the sputtering target 2 and the backing plate 1, by the intermediate layer 24, can further suppress damage to and warpage of the sputtering target 2 due to repeated expansion by heating and contraction by cooling. In addition, as the intermediate layer 24 is provided, the joining strength between the bottom surface 9 of the sputtering target 2 and the recessed section bottom surface 7 of the backing plate can be improved, and the adhesion can be improved to maintain favorable thermal conduction. In addition, since the intermediate layer 24 is provided in the recessed section 4 of the backing plate 1 and the intermediate layer 24 is covered with the sputtering target 2, it is possible to keep the material of the intermediate layer 24 from being evaporated and becoming impurities and adhering to a substrate. The reason why the elements of In and Zn are selected for the intermediate layer 24 is that the elements are suitable from the viewpoint of the adhesion, thermal conduction, and linear expansion coefficient. In an example where the intermediate layer 24 is a plate material, when the plate material is thicker than 1.0 mm, the recessed section of the backing plate 1 needs to be deeper, and thus, the thickness of the backing plate 1 may need to be increased. In an example where the intermediate layer 24 is a powder layer, the intermediate layer 24 has a powder form by heating, a sintered powder form, or a form in which powder is melted by heating. The form in which the powder is melted by heating is similar to the form in which the intermediate layer 24 is the plate material. The intermediate layer 24 is preferably provided between the bottom surface 9 of the sputtering target 2 and the recessed section bottom surface 7 of the backing plate, but may be further provided on an interface between the outer-peripheral-side surface 5 of the sputtering target 2 and the recessed section inner-peripheral-side surface 6 of the recessed section 4 of the backing plate.

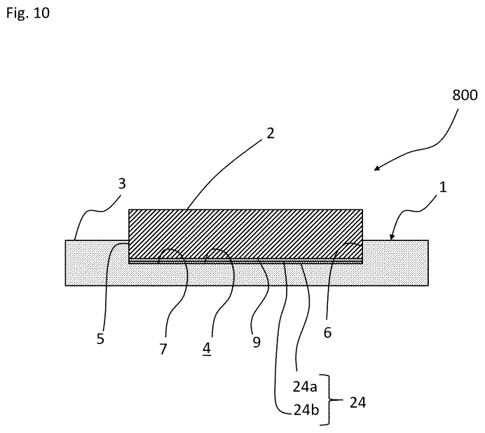

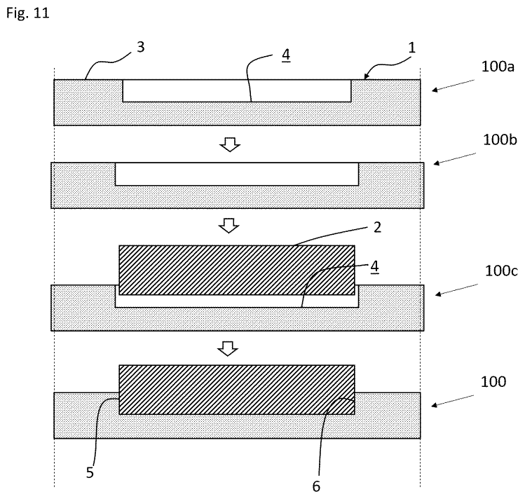

As illustrated in FIG. 10, the sputtering target-backing plate assembly 800 according to the present embodiment includes two intermediate layers 24 on the interface between the sputtering target 2 and the backing plate 1, and it is preferable that the intermediate layer 24a is composed of a plate material having a thickness of 2.5 mm or less or powder and formed of at least one metal of Ni, Cr, Al, or Cu or an alloy containing at least one of Ni, Cr, Al, or Cu, or a combination of the plate material and the powder, is composed of a thin film having a thickness of 10 μm or less and formed of at least one metal of Ni, Cr, Al, or Cu or an alloy containing at least one of Ni, Cr, Al, or Cu, or is composed of a plate material having a thickness of 1.0 mm or less or powder and formed of at least one metal of In or Zn or an alloy containing at least one of In or Zn, or a combination of the plate material and the powder, and the intermediate layer 24b is composed of a plate material having a thickness of 2.5 mm or less or powder and formed of at least one metal of Ni, Cr, Al, or Cu or an alloy containing at least one of Ni, Cr, Al, or Cu, or a combination of the plate material and the powder, is composed of a thin film having a thickness of 10 μm or less and formed of at least one metal of Ni, Cr, Al, or Cu or an alloy containing at least one of Ni, Cr, Al, or Cu, or is composed of a plate material having a thickness of 1.0 mm or less or powder and formed of at least one metal of In or Zn or an alloy containing at least one of In or Zn, or a combination of the plate material and the powder. Reducing the difference in linear expansion coefficient between the sputtering target 2 and the backing plate 1, by the intermediate layer 24, can further suppress damage to and warpage of the sputtering target 2 due to repeated expansion by heating and contraction by cooling. The reason why the intermediate layer 24a provided on the interface with the backing plate 1 is formed of various forms of materials including at least one metal of Ni, Cr, Al, or Cu or an alloy containing at least one of Ni, Cr, Al, or Cu, and at least one metal of In or Zn or an alloy containing at least one of In or Zn is that these materials are suitable from the viewpoint of the adhesion, thermal conduction, and linear expansion coefficient. Further, the reason why the intermediate layer 24b provided on the interface with the sputtering target 2 is formed of various forms of materials including at least one metal of Ni, Cr, Al, or Cu or an alloy containing at least one of Ni, Cr, Al, or Cu, and at least one metal of In or Zn or an alloy containing at least one of In or Zn is that these materials are suitable from the viewpoint of the adhesion, thermal conduction, and linear expansion coefficient. Although FIG. 10 illustrates a form in which two intermediate layers are provided, but the number of intermediate layers may be three or more layers as long as the effect of the intermediate layer described above is obtained.

In the sputtering target-backing plate assembly according to the present embodiment, the material of the sputtering target 2 can be an Al—Sc alloy, Ru, a Ru alloy, Ir, or an Ir alloy. In addition, a Li-based oxide, a Co-based oxide, a Ti-based oxide, an Mg-based oxide, or the like can also be used. Even with a material having a high melting point of 1000° C. or higher, it is possible to improve the joining strength between the sputtering target and the backing plate while suppressing warpage and cracking of the sputtering target.

In the sputtering target-backing plate assembly according to the present embodiment, the material of the backing plate 1 is Al, an Al alloy, Cu, a Cu alloy, Fe, or an Fe alloy, and the linear expansion coefficient is preferably 30.0×10⁻⁶/° C. or less. The linear expansion coefficient is preferably 28.5×10⁻⁶/° C. or less, and more preferably 27.3×10⁻⁶/° C. or less. In a condition where the linear expansion coefficient is larger than 30.0×10⁻⁶/° C., the sputtering target is cracked or warped due to repeated expansion by heating and contraction by cooling of the backing plate 1, so that the linear expansion coefficient is preferably 30.0×10⁻⁶/° C. or less. In addition, as the backing plate having a favorable thermal conductivity is used, the backing plate is expanded during a period of heating, so that the sputtering target can be inserted into the recessed section of the backing plate, and the backing plate is contracted during a period of cooling, so that the outer-peripheral-side surface of the sputtering target can be swaged with the recessed section inner-peripheral-side surface of the backing plate to form the assembly. A lower limit of the linear expansion coefficient is preferably 6.0×10⁻⁶/° C. or more.

The sputtering target-backing plate assembly according to the present embodiment can also be applied to a sputtering target 2 having a flexural strength of 500 MPa or less. The present embodiment can also be applied to a sputtering target having a low flexural strength. The flexural strength is measured, for example, based on the standard of JIS R 1601:2008.

[Relational Expression Including Linear Expansion Coefficient] (Common ΔT)

In the sputtering target-backing plate assembly according to the present embodiment, a planar shape of the recessed section 4 of the backing plate 1 is preferably a circular shape or a rectangular shape including a square shape, and a relationship between a diameter or side length of the recessed section 4 of the backing plate 1 and a diameter or side length of the sputtering target preferably satisfies (Expression 1) to (Expression 5):

D_{TG}>D_{BP} (Expression 1)

D_{BP}=D_{TG}−ΔD×C (Expression 2)

ΔD=D_{BP}×ΔT×CTE_{BP}−D_{TG}×ΔT×CTE_{TG} (Expression 3)

D_{TG}−ΔD×4.0≤D_{BP}≤D_{TG}−ΔD×0.5 (Expression 4)

CTE_{BP}>CTE_{TG} (Expression 5)
where D_{BP}, D_{TG}, ΔD, C, T, ΔT, CTE_{BP}, and CTE_{TG} mean the following:
D_{BP}: the diameter or side length (mm) of the recessed section of the backing plate at room temperature
D_{TG}: the diameter or side length (mm) of the sputtering target at the room temperature
T: a temperature (° C.) at which the backing plate is thermally expanded to fit the sputtering target (where T>the room temperature)
ΔT: T—the room temperature (° C.)
CTE_{BP}: the linear expansion coefficient (1/° C.) of the backing plate at the temperature T
CTE_{TG}: the linear expansion coefficient (1/° C.) of the sputtering target at the temperature T
C: a coefficient (where C=0.5 to 4.0)
ΔD: a difference (mm) in thermal expansion amount between the backing plate and the sputtering target under the condition of rising a temperature from the room temperature to the temperature T

Here, when the planar shape of the recessed section 4 of the backing plate 1 is a rectangular shape, a long side of the sputtering target 2 is made to correspond to a long side of the recessed section 4 of the backing plate 1, and a short side of the sputtering target 2 is made to correspond to a short side of the recessed section 4 of the backing plate 1. As shown in (Expression 1), at the room temperature, the sputtering target 2 is larger than the recessed section 4 of the backing plate 1, and thus, the sputtering target 2 cannot be inserted into the recessed section 4 of the backing plate 1. Here, the room temperature is 25° C. Here, a form in which both the backing plate 1 and the sputtering target 2 are heated to the temperature T is considered as Form (1). When the temperature of the recessed section 4 of the backing plate 1 is raised from the room temperature to the temperature T at which the backing plate is thermally expanded, the diameter or side length of the recessed section 4 is increased, by the thermal expansion, by a length obtained by (D_{BP}×ΔT×CTE_{BP}). In addition, when the temperature of the sputtering target 2 is raised from the room temperature to the temperature T, the diameter or side length of the sputtering target 2 is increased, by the thermal expansion, by a length obtained by (D_{TG}×ΔT×CTE_{TG}). Therefore, on the assumption of the linear expansion coefficients satisfying the relationship of (Expression 5), when both the temperatures of the recessed section 4 of the backing plate 1 and the sputtering target 2 are raised to the temperature T, the diameter or side length of the recessed section 4 is increased more, by the thermal expansion, than the diameter or side length of the sputtering target 2 by a length of ΔD. When the diameter or side length of the recessed section 4 becomes the same as or larger than the diameter or side length of the sputtering target 2 by the thermal expansion, the sputtering target 2 can be fitted into the recessed section 4. Then, when the temperature is lowered to the room temperature, the swaging structure is formed according to the relationship shown in (Expression 1). In Form (1) described above, in order to be able to form the swaging structure, thermal expansion of the recessed section 4 needs to make the diameter or side length of the recessed section 4 exceed the diameter or side length of the sputtering target 2. In this regard, (Expression 2) and (Expression 4) show the relationship of the settable minimum diameter or side length of the recessed section 4 at the room temperature in comparison with the diameter or side length of the sputtering target 2 at the room temperature. In (Expression 2) and (Expression 4), C is the coefficient, but in a condition where C is in a range of 0.5 to 4.0, with the sputtering target and the backing plate joined by swaging between the outer-peripheral-side surface of the sputtering target and the recessed section inner-peripheral-side surface of the backing plate, cracking and warpage of the sputtering target can be suppressed, and the swaging structure having a favorable strength can be formed.

The present embodiment includes Form (1) in which the temperatures of both of the recessed section 4 of the backing plate 1 and the sputtering target 2 are raised to the temperature T as described above, Form (2) in which the temperature of the recessed section 4 of the backing plate 1 is raised to the temperature T and the temperature of the sputtering target 2 is raised only to a temperature T₁ lower than the temperature T, and Form (3) in which the temperature of the recessed section 4 of the backing plate 1 is raised to the temperature T and the temperature of the sputtering target 2 is not raised.

[Relational Expression Including Linear Expansion Coefficient] (Different Between ΔT (BP) and ΔT₁ (TG))

In the sputtering target-backing plate assembly according to the present embodiment, a planar shape of the recessed section 4 of the backing plate 1 is preferably a circular shape or a rectangular shape including a square shape, and a relationship between a diameter or side length of the recessed section 4 of the backing plate 1 and a diameter or side length of the sputtering target preferably satisfies (Expression 6) to (Expression 10):

D_{TG}>D_{BP} (Expression 6)

D_{BP}=D_{TG}−ΔD×C (Expression 7)

ΔD=D_{BP}×ΔT×CTE_{BP}−D_{TG}×ΔT₁×CT₁E_{TG} (Expression 8)

D_{TG}−ΔD×4.0≤D_{BP}≤D_{TG}−ΔD×0.5 (Expression 9)

CTE_{BP}>CT₁E_{TG} (Expression 10)
where D_{BP}, D_{TG}, ΔD, C, T, ΔT, T₁, ΔT₁, CTE_{BP}, and CT₁E_{TG} mean the following:
D_{BP}: the diameter or side length (mm) of the recessed section of the backing plate at room temperature
D_{TG}: the diameter or side length (mm) of the sputtering target at the room temperature
T: a temperature (° C.) of the backing plate when the backing plate is thermally expanded to fit the sputtering target (where T>the room temperature and T>T₁)
ΔT: T—the room temperature (° C.)
T₁: a temperature (° C.) of the sputtering target when the backing plate is thermally expanded to fit the sputtering target (where T₁>the room temperature and T>T₁)
ΔT₁: T₁—the room temperature (° C.)
CTE_{BP}: the linear expansion coefficient (1/° C.) of the backing plate at the temperature T
CT₁E_{TG}: the linear expansion coefficient (1/° C.) of the sputtering target at the temperature T₁
C: a coefficient (where C=0.5 to 4.0)
ΔD: a difference (mm) between a thermal expansion amount of the backing plate under the condition of rising a temperature from the room temperature to the temperature T and a thermal expansion amount of the sputtering target under the condition of rising a temperature from the room temperature to the temperature T₁

Here, similarly considering Form (3), when the temperature of the recessed section 4 of the backing plate 1 is raised from the room temperature to the temperature T at which the backing plate is thermally expanded, the diameter or side length of the recessed section 4 is increased, by the thermal expansion, by a length obtained by (D_{BP}×ΔT×CTE_{BP}). In addition, since the sputtering target 2 remains at the room temperature, the diameter or side length of the sputtering target 2 is not increased by the thermal expansion. Then, when only the recessed section 4 of the backing plate 1 is thermally expanded by raising the temperature to the temperature T, thermal expansion is performed by a length obtained by (D_{BP}×ΔT×CTE_{BP}), and the diameter or side length of the recessed section of the backing plate 1 is increased more, by the thermal expansion, than the diameter or side length of the sputtering target 2, so that the sputtering target 2 can be fitted into the recessed section 4. Then, when the temperature is lowered to the room temperature, the swaging structure is formed according to the relationship shown in (Expression 6). In Form (3) described above, in order to be able to form the swaging structure, thermal expansion of the recessed section 4 needs to make the diameter or side length of the recessed section 4 exceed the diameter or side length of the sputtering target 2. In this regard, (Expression 7) and (Expression 9) show the relationship of the settable minimum diameter or side length of the recessed section 4 at the room temperature in comparison with the diameter or side length of the sputtering target 2 at the room temperature. In (Expression 7) and (Expression 9), C is the coefficient, but in a condition where C is in a range of 0.5 to 4.0, with the sputtering target and the backing plate joined by swaging between the outer-peripheral-side surface of the sputtering target and the recessed section inner-peripheral-side surface of the backing plate, cracking and warpage of the sputtering target can be suppressed, and the swaging structure having a favorable strength can be formed.

Since Form (2) is an intermediate form between Form (1) and Form (3), the swaging structure is similarly formed.

The sputtering target-backing plate assembly according to the present embodiment includes a form in which the sputtering target 2 is fitted into the backing plate such that the plate surface of the backing plate 1 is exposed to an entire periphery of a target surface of the sputtering target in order to easily set the sputtering target-backing plate assembly in the sputtering equipment. This form is illustrated, for example, in FIG. 1 or FIG. 3.

The sputtering target-backing plate assembly according to the present embodiment includes a form in which the target surface of the sputtering target protrudes from the plate surface of the backing plate in order to enable joining by pressing only the target surface of the sputtering target in manufacturing the sputtering target-backing plate assembly. This form is illustrated, for example, in FIGS. 11 to 14 and the like.

Next, a first example of a manufacturing method for the sputtering target-backing plate assembly 100 illustrated in FIG. 2 will be described with reference to FIG. 11. The manufacturing method for the sputtering target-backing plate assembly 100 according to the present embodiment includes: a step 1 of preparing the sputtering target 2 having a thickness of 2.0 to 15.0 mm and the backing plate 1 (not illustrated in FIG. 11); a step 2 of forming the recessed section 4 having the depth of 0.5 to 5.0 mm in the plate surface 3 of the backing plate 1 (100a of FIG. 11); a step 3 of heating the backing plate 1 to thermally expand the recessed section 4 (100b of FIG. 11); a step 4 of fitting the sputtering target 2 into the thermally expanded recessed section 4 (a state where the fitting is being performed is illustrated in 100c of FIG. 11); and a step 5 of cooling the backing plate 1 to form the swaging structure in which the outer-peripheral-side surface 5 of the sputtering target 2 is clamped by the recessed section inner-peripheral-side surface 6 of the backing plate 1 (100 of FIG. 11). Thereat, the diameter (in an example of fitting a disk-shaped sputtering target) or side length (in an example of fitting a sputtering target whose planar shape is a rectangular shape) of the recessed section 4 in the step 2 is slightly smaller than the diameter or side length of the sputtering target, and the backing plate 1 is heated and is expanded so that the recessed section inner-peripheral-side surface 6 of the recessed section 4 becomes slightly larger than the outer-peripheral-side surface 5 of the sputtering target 2, whereby the recessed section 4 of the backing plate 1 can be filled with the sputtering target 2. Then, the backing plate 1 is contracted by the cooling in the step 5, the outer-peripheral-side surface 5 of the sputtering target 2 is tightened by the recessed section inner-peripheral-side surface 6 of the backing plate 1, and joining can be performed with swaging by the contraction during cooling. In the step 3, the backing plate 1 is heated, but the sputtering target 2 is not heated together therewith. The sputtering target 2 may be heated by heat conduction from the backing plate 1. Then, in the step 5, the temperature of the sputtering target 2 can be lowered as the backing plate 1 is cooled. The backing plate 1 is heated by using, for example, a hot plate.

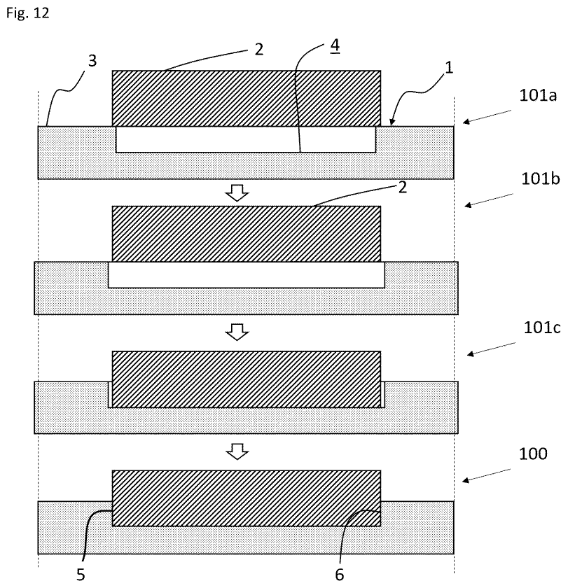

Next, a second example of a manufacturing method for the sputtering target-backing plate assembly 100 illustrated in FIG. 2 will be described with reference to FIG. 12. Both the backing plate 1 and the sputtering target 2 are heated. The heating can be performed by, for example, a hot press (HP) sintering method, a hot isostatic pressing (HIP) sintering method, a spark plasma sintering (SPS) method, or the like. The manufacturing method for the sputtering target-backing plate assembly 100 according to the present embodiment includes: a step 1 of preparing the sputtering target 2 having a thickness of 2.0 to 15.0 mm and the backing plate 1 (not illustrated in FIG. 12); a step 2 of forming the recessed section 4 having the depth of 0.5 to 5.0 mm in the plate surface 3 of the backing plate 1 (not illustrated in FIG. 12); a step 2-1 of setting the sputtering target 2 over the recessed section 4 of the backing plate 1 (101a of FIG. 12); a step 3 of heating the backing plate 1 to thermally expand the recessed section 4 (101b of FIG. 12); a step 3-1 of heating the sputtering target 2 in the step 3 (101b of FIG. 12); a step 4 of fitting the sputtering target 2 into the thermally expanded recessed section 4 (101c of FIG. 12); and a step 5 of cooling the sputtering target 2 and the backing plate 1 to form the swaging structure in which the outer-peripheral-side surface 5 of the sputtering target 2 is clamped by the recessed section inner-peripheral-side surface 6 of the backing plate 1 (100 of FIG. 12). Thereat, the diameter (in an example of fitting a disk-shaped sputtering target) or side length (in an example of fitting a rectangular sputtering target) of the recessed section 4 in the step 2 is slightly smaller than the diameter or side length of the sputtering target, and the backing plate 1 is heated and is expanded so that the recessed section inner-peripheral-side surface 6 of the recessed section 4 becomes slightly larger than the outer-peripheral-side surface 5 of the sputtering target 2, whereby the recessed section 4 of the backing plate 1 can be filled with the sputtering target 2. Then, the backing plate 1 is contracted more, by the cooling in the step 5, than the sputtering target 2, the outer-peripheral-side surface 5 of the sputtering target 2 is tightened by the recessed section inner-peripheral-side surface 6 of the backing plate 1, and joining can be performed with swaging by the contraction during cooling.

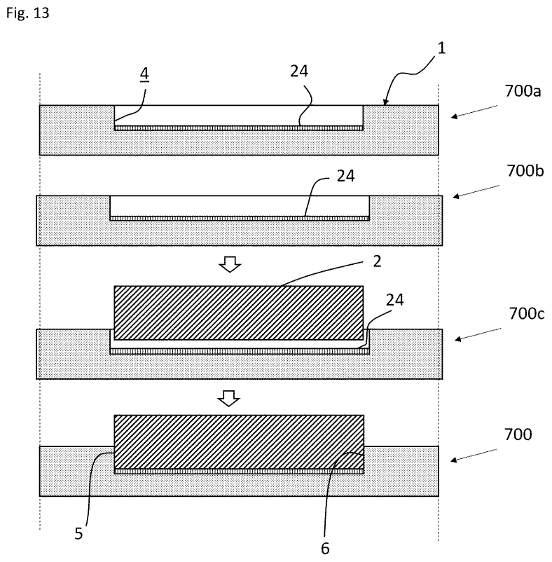

As illustrated in FIG. 13, according to the present embodiment, the manufacturing method may further include, between the step 2 and the step 3 or between the step 3 and the step 4, a step 6 of filling or coating the recessed section 4 with a material of the intermediate layer 24. Specifically, in FIG. 13, the recessed section 4 of the backing plate 1 before thermal expansion is filled with the material of the intermediate layer 24 (700a of FIG. 13), and the thermally expanded recessed section 4 of the backing plate 1 is filled with the material of the intermediate layer 24 (700b of FIG. 13). Thereafter, the sputtering target 2 is fitted into the recessed section 4 of the backing plate 1 (a state where the fitting is being performed is illustrated in 700c of FIG. 13), and the backing plate 1 is cooled to form the swaging structure in which the outer-peripheral-side surface 5 of the sputtering target 2 is clamped by the recessed section inner-peripheral-side surface 6 of the backing plate 1 (700 of FIG. 13), whereby the sputtering target-backing plate assembly including the intermediate layer illustrated in FIG. 9 can be manufactured.

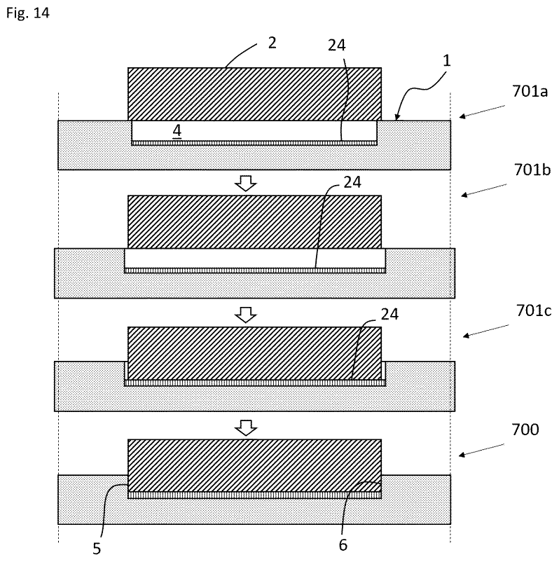

As illustrated in FIG. 14, in an example of heating both the backing plate 1 and the sputtering target 2, the manufacturing method may further include, between the step 2 and the step 2-1, a step 6 of filling or coating the recessed section 4 with the material of the intermediate layer 24 (701a of FIG. 14). Thereafter, the recessed section 4 of the backing plate 1 is thermally expanded (701b of FIG. 14), the sputtering target 2 is heated (701b of FIG. 14), the sputtering target 2 is fitted into the recessed section 4 of the backing plate 1 (701c of FIG. 14), and the sputtering target 2 and the backing plate 1 are cooled to form the swaging structure in which the outer-peripheral-side surface 5 of the sputtering target 2 is clamped by the recessed section inner-peripheral-side surface 6 of the backing plate 1 (700 of FIG. 14), whereby the sputtering target-backing plate assembly including the intermediate layer illustrated in FIG. 9 can be manufactured.

In an example where two intermediate layers 24 are provided as in the sputtering target-backing plate assembly 800 illustrated in FIG. 10, the sputtering target-backing plate assembly 800 can be manufactured by forming two intermediate layers 24 in a stacked state in forming the intermediate layers 24 in FIG. 13 or 14. FIG. 10 illustrates a form in which two intermediate layers are provided, but the number of intermediate layers may be three or more layers as long as the effect of the intermediate layer described above is obtained.

In the present embodiment, the manufacturing method preferably further includes, between the step 4 and the step 5, a step 7 of pressing the sputtering target 2 to diffuse the bottom surface 9 of the sputtering target 2 and the recessed section bottom surface 7 of the backing plate 1. Since the surfaces are brought into close contact with each other by the pressing, diffusion between the sputtering target 2 and the backing plate 1, or diffusion between the sputtering target 2 and the intermediate layer 24 and diffusion between the intermediate layer 24 and the backing plate 1 can be performed, so that adhesion is improved and thermal conduction can be excellently maintained. In addition, pressing the sputtering target 2 also helps to prevent warpage of the sputtering target during contraction.

In the present embodiment, at least the step 3, the step 4, and the step 5 are preferably performed by using at least one of the hot press (HP) sintering method, the hot isostatic pressing (HIP) sintering method, the spark plasma sintering (SPS) method, or a heating method using a hot plate. Any equipment capable of performing heating and cooling can be applied, and at least one of the hot press (HP) sintering method, the hot isostatic pressing (HIP) sintering method, the spark plasma sintering (SPS) method, or the heating method using a hot plate can be used. The cooling includes natural cooling.

In the present embodiment, the step 7 is preferably performed using at least one of the hot press (HP) sintering method, the hot isostatic pressing (HIP) sintering method, or the spark plasma sintering (SPS) method. Any equipment capable of simultaneously performing heating and pressing can be applied, and any of the hot press (HP) sintering method, the hot isostatic pressing (HIP) sintering, and the spark plasma sintering (SPS) method can be used.

In the present embodiment, in the step 7, it is preferable that a reduced-pressure atmosphere of 10 Pa or less or an atmosphere having an oxygen concentration of 1000 ppm or less is set, a heating temperature is set to 100 to 1000° C., and the pressing force is set to a range of 0 Pa or more and 80 MPa or less. An oxygen content of the sputtering target can be reduced.

After the sputtering target-backing plate assembly is manufactured by the hot plate method, heating and pressing may be further performed again by using the spark plasma sintering (SPS) method or the like.

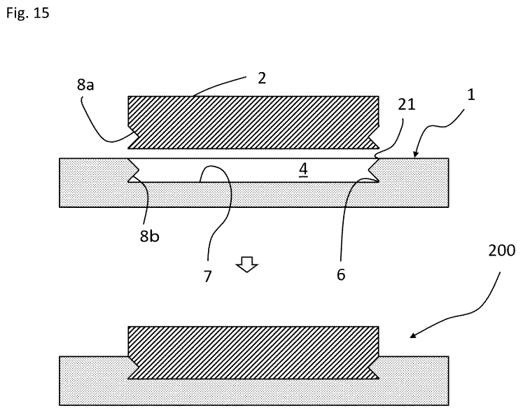

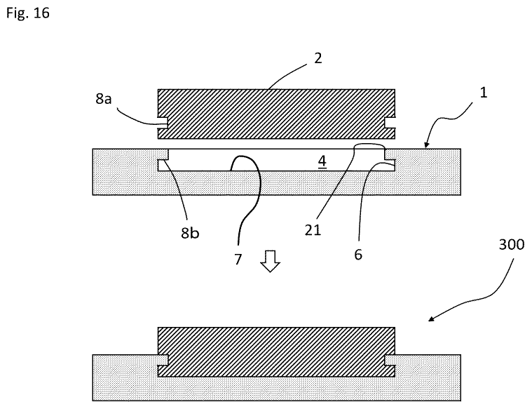

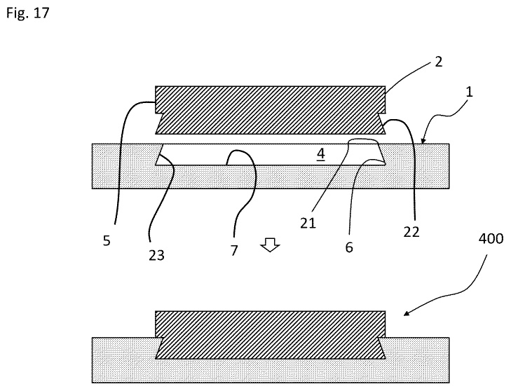

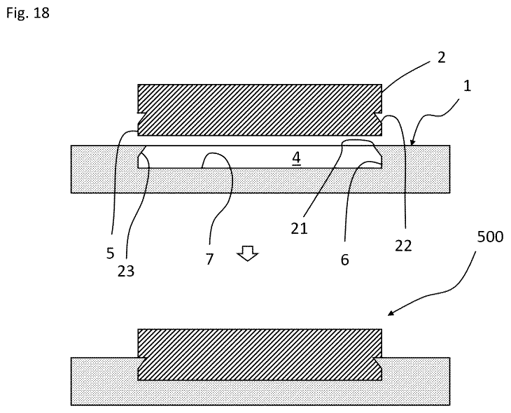

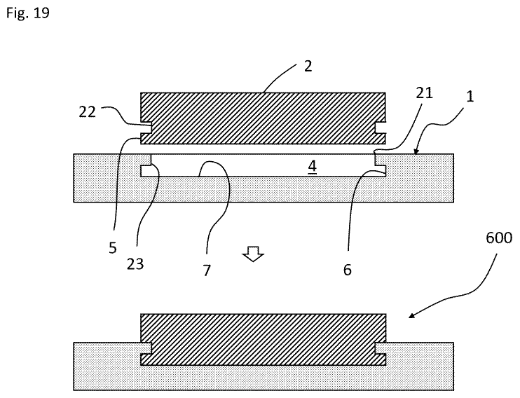

The sputtering target-backing plate assembly 200 illustrated in FIG. 4 can be manufactured by thermally expanding the backing plate 1 and by cooling the backing plate 1 after fitting the sputtering target 2, as illustrated in FIG. 15. Further, the sputtering target-backing plate assembly 300 illustrated in FIG. 5 can be manufactured by thermally expanding the backing plate 1 and by cooling the backing plate 1 after fitting the sputtering target 2, as illustrated in FIG. 16. Further, the sputtering target-backing plate assembly 400 illustrated in FIG. 6 can be manufactured by thermally expanding the backing plate 1 and by cooling the backing plate 1 after fitting the sputtering target 2, as illustrated in FIG. 17. Further, the sputtering target-backing plate assembly 500 illustrated in FIG. 7 can be manufactured by thermally expanding the backing plate 1 and by cooling the backing plate 1 after fitting the sputtering target 2, as illustrated in FIG. 18. Further, the sputtering target-backing plate assembly 600 illustrated in FIG. 8 can be manufactured by thermally expanding the backing plate 1 and by cooling the backing plate 1 after fitting the sputtering target 2, as illustrated in FIG. 19.

In the present embodiment, after the step 5, it is preferable to perform a pair of the pressing or heating and pressing step and the cooling step once or repeatedly twice or more. As the pair of the pressing or heating and pressing step and the cooling step is performed once or repeatedly twice or more, it is possible to further improve the joining strength between the bottom surface of the sputtering target and the recessed section bottom surface of the backing plate and further improve the adhesion to more efficiently perform heat conduction.

An example where the sputtering target-backing plate assembly according to the present embodiment is mounted on the sputtering equipment and used, and an example where the sputtering target is consumed will be described. A recovery method for the sputtering target according to the present embodiment includes: a step A of heating the sputtering target-backing plate assembly according to the present embodiment to thermally expand the recessed section opening surface 21 of the backing plate 1 until making the recessed section opening surface 21 larger than the bottom surface 9 of the sputtering target 2; and a step B of detaching the sputtering target 2 from the backing plate 1 to recover the sputtering target from the sputtering target-backing plate assembly. The form in which the sputtering target 2 is detached includes a form in which the sputtering target 2 is detached as it is and a form in which an impact is applied to the sputtering target 2 to make the sputtering target 2 detached.

### EXAMPLES

Hereinafter, the present invention will be described in more detail with reference to Examples, but the present invention is not construed as being limited to Examples.

### Example 1

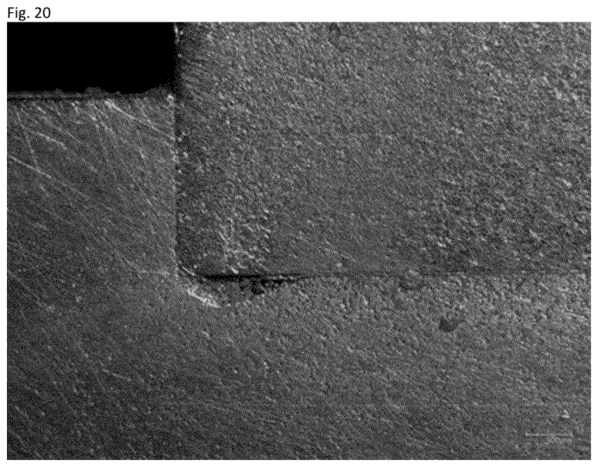

An assembly corresponding to FIG. 9 is produced. First, an AI-30 atom % Sc sputtering target 2 of ϕ50×7t (unit: mm) having a flexural strength of 138 MPa and a backing plate 1 of A6061 which is an Al alloy of ϕ70×8t (unit: mm) were prepared. The linear expansion coefficient of AI-30 atom % Sc is 13.5×10⁻⁶/° C. and the linear expansion coefficient of A6061 is 23.6×10⁻⁶/° C. Next, the recessed section 4 having a diameter smaller than the diameter of the sputtering target 2 by 0.1 mm and having a depth of 2 mm was formed at a setting location of the sputtering target 2 on the backing plate 1 by a lathe. Next, the recessed section bottom surface 7 of the backing plate 1 was filled with a Ni plate material having a thickness of 0.1 mm as the material of the intermediate layer 24. Next, the AI-30 atom % Sc sputtering target 2 was set over the recessed section 4 of the backing plate 1. At this time, the sputtering target 2 is not fitted in the recessed section 4 but is located above the Ni plate material (with a gap of 2 mm from the recessed section bottom surface 7). Next, after a temperature rise to 250° C. under a reduced-pressure atmosphere of 10 Pa or less using a spark plasma sintering machine, the recessed section 4 of the backing plate 1, of which the recessed section opening surface 21 was thermally expanded, was filled with the sputtering target 2. Thereafter, the temperature was raised to 400° C. and maintained for one hour to perform diffusion joining while pressing the sputtering target 2 at 10 MPa. Thereafter, cooling was performed to form the swaging structure. The result is illustrated in FIG. 20. As illustrated in FIG. 20, the outer-peripheral-side surface 5 of the sputtering target 2 and the recessed section inner-peripheral-side surface 6 of the backing plate 1 were fixed by swaging, and filling with Ni is performed without a gap from the target bottom surface 9, and as a result, the diffusion joining was performed with favorable thermal conduction, and at this time, cracking of the target did not occur.

### Example 2

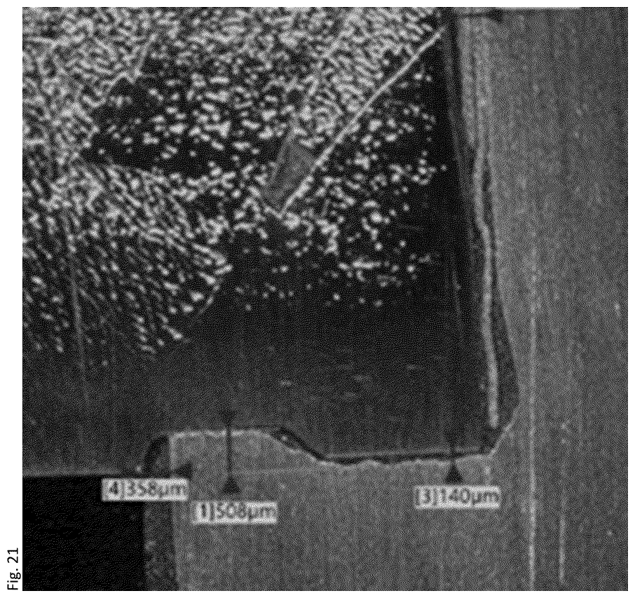

An assembly in which the intermediate layer is further provided in the assembly corresponding to FIG. 5 is manufactured. First, a ruthenium sputtering target 2 of ϕ156×9t (unit: mm) produced by a melting method and a brass backing plate 1 of ϕ240×20t (unit: mm) were prepared. The linear expansion coefficient of ruthenium is 6.75×10⁻⁶/° C., and the linear expansion coefficient of brass is 21.2×10⁻⁶/° C. Next, an annular recessed section having a depth of 0.5 mm was formed in the outer-peripheral-side surface 5 of the sputtering target 2 in a peripheral direction of the side surface by a lathe. As a result, an annular protruding section that protrudes based on a bottom surface of the annular recessed section was formed on the outer-peripheral-side surface 5 of the sputtering target 2. Next, the recessed section 4 having a diameter smaller than the diameter of the sputtering target 2 by 0.4 mm and having a depth of 4 mm was formed at a setting location of the sputtering target 2 on the backing plate 1 by a lathe. Further, an annular recessed section having a depth of 0.5 mm was formed in the recessed section inner-peripheral-side surface 6 of the backing plate 1 at a position corresponding to the annular protruding section of the sputtering target 2. Next, the recessed section bottom surface 7 of the backing plate 1 was filled with a Ni plate material having a thickness of 0.1 mm and a trace amount of In powder. A gap around the Ni plate material is filled with the trace amount of In powder. Next, the sputtering target 2 was set over the recessed section 4 of the backing plate 1. Next, after a temperature rise to 250° C. under a reduced-pressure atmosphere of 10 Pa or less using a spark plasma sintering machine, the recessed section of the backing plate 1 was filled with the sputtering target 2. After the filling, the temperature was raised to 400° C. and maintained for one hour to perform diffusion joining while pressing the sputtering target 2 at 10 MPa, and then, cooling was performed for swaging. The result is illustrated in FIG. 21. The assembly has a structure in which the uneven portion of the outer-peripheral-side surface 5 of the sputtering target 2 and the uneven portion of the recessed section inner-peripheral-side surface 6 of the backing plate 1 are fitted to each other. As illustrated in FIG. 21, the outer-peripheral-side surface 5 of the sputtering target 2 and the recessed section inner-peripheral-side surface 6 of the backing plate 1 were fixed by swaging, and filling with Ni and In is performed without a gap from the target bottom surface 9, and as a result, the diffusion joining was performed with favorable thermal conduction, and cracking of the target did not occur.

### Comparative Example 1

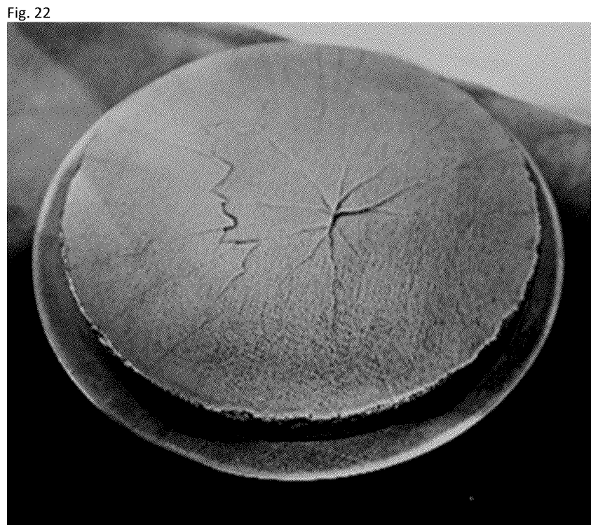

An AI-30 atom % Sc sputtering target of ϕ70×7t (unit: mm) having a flexural strength of 138 MPa and a backing plate of A6061 which is an Al alloy of ϕ80×8t (unit: mm) were prepared. The linear expansion coefficient of AI-30 atom % Sc is 13.5×10⁻⁶/° C. and the linear expansion coefficient of A6061 is 23.6×10⁻⁶/° C. Next, the AI-30 atom % Sc sputtering target was set on the backing plate. Next, after a temperature rise to 500° C. in a vacuum atmosphere using a spark plasma sintering machine, diffusion joining was performed by holding the sputtering target at 10 MPa for one hour while pressing the sputtering target. The result is illustrated in FIG. 22. In the assembly, the recessed section 4 is not formed in the backing plate, and thus, the assembly does not have the swaging structure. As illustrated in FIG. 22, the sputtering target and the backing plate are joined, but since the difference in linear expansion coefficient is large, the sputtering target is cracked due to a compressive stress at the time of cooling the backing plate.

### Comparative Example 2

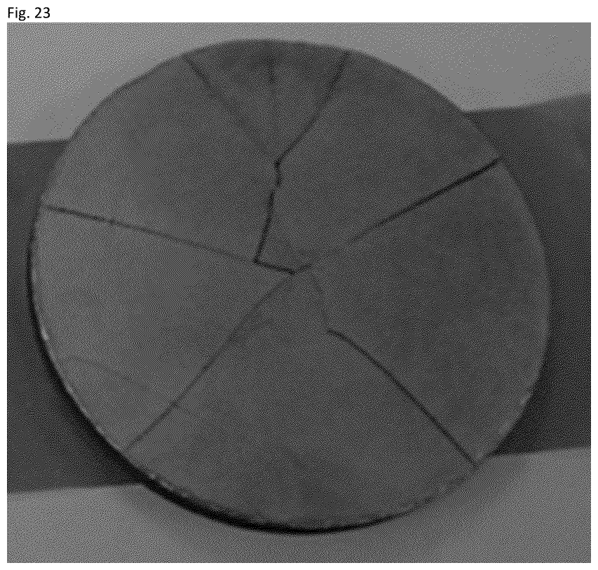

An AI-30 atom % Sc sputtering target of ϕ70×7t (unit: mm) having a flexural strength of 138 MPa and a backing plate of aluminum bronze which is an Al alloy of ϕ80×8t (unit: mm) were prepared. The linear expansion coefficient of AI-30 atom % Sc is 13.5×10⁻⁶/° C. and the linear expansion coefficient of aluminum bronze is 16.5×10⁻⁶/° C. Next, the AI-30 atom % Sc sputtering target was set on the backing plate. Next, after a temperature rise to 500° C. in a vacuum atmosphere using a spark plasma sintering machine, diffusion joining was performed by holding the sputtering target at 10 MPa for one hour while pressing the sputtering target. The result is illustrated in FIG. 23. In the assembly, the recessed section 4 is not formed in the backing plate, and thus, the assembly does not have the swaging structure. As illustrated in FIG. 23, the linear expansion coefficient of the sputtering target and the linear expansion coefficient of the backing plate were closer to each other than in Comparative Example 1, but since there was a difference in linear expansion coefficient between the sputtering target and the backing plate, the sputtering target was cracked due to a compressive stress, and the sputtering target was peeled from the backing plate due to insufficient joining to the backing plate.

### Comparative Example 3

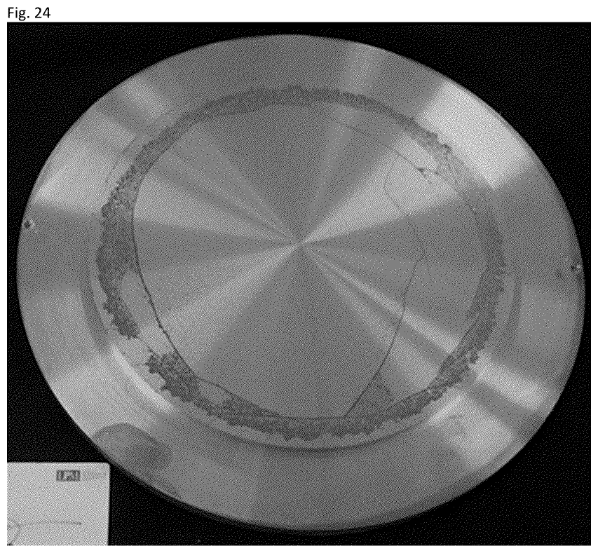

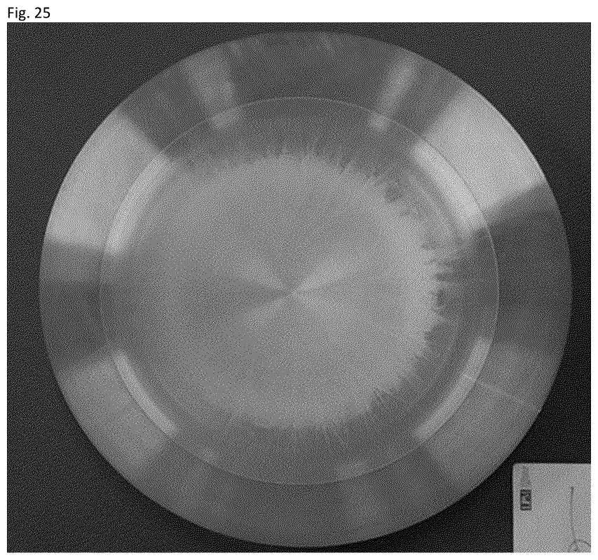

A ruthenium sputtering target of ϕ194×10t (unit: mm) and an oxygen-free copper backing plate of ϕ240×20t (unit: mm) were prepared by a sintering method. The linear expansion coefficient of ruthenium is 6.75×10⁻⁶/° C., and the linear expansion coefficient of oxygen-free copper is 16.2×10⁻⁶/° C. Next, the ruthenium sputtering target was set on the backing plate. Next, after a temperature rise to 700° C. in a vacuum atmosphere using a spark plasma sintering machine, diffusion joining was performed by holding the sputtering target at 10 MPa for one hour while pressing the sputtering target. The result is illustrated in FIG. 24. In the assembly, the recessed section 4 is not formed in the backing plate, and thus, the assembly does not have the swaging structure. As illustrated in FIG. 24, since there was a difference in linear expansion coefficient between the sputtering target and the backing plate, the sputtering target was cracked due to a compressive stress.

### Comparative Example 4

A ruthenium sputtering target of ϕ180×5t (unit: mm) and an oxygen-free copper container having a thickness of 15 mm, which is called CAN and used as a backing plate and in which a recessed section of ϕ180.1 mm having a depth of 10 mm is formed, were prepared by a sintering method. The linear expansion coefficient of ruthenium is 6.75×10⁻⁶/° C., and the linear expansion coefficient of oxygen-free copper is 16.2×10⁻⁶/° C. Next, after the sputtering target was contained in the CAN, an oxygen-free copper lid of ϕ180×5t was set on the sputtering target from above, and the inside of the CAN was vacuumed and sealed. Next, after a temperature rise to 500° C. using a HIP equipment, the CAN was pressurized at 100 MPa to perform diffusion joining. At this time, the container was pressurized over the entire surface, and the container and the target were subjected to diffusion joining. After the diffusion joining, the sputtering target and the backing plate were cut using a lathe. The result is illustrated in FIG. 25. As illustrated in FIG. 25, diffusion joining was performed, but since there was a difference in linear expansion coefficient between the sputtering target and the backing plate, fine cracks were radially generated in the sputtering target from the central portion toward the outer periphery due to a compressive stress.

### REFERENCE SIGNS LIST

50, 100, 200, 300, 400, 500, 600, 700, 800 Sputtering target-backing plate assembly
1 Backing plate
2 Sputtering target
3 Plate surface of backing plate
4 Recessed section of backing plate
Outer-peripheral-side surface of sputtering target
6 Recessed section inner-peripheral-side surface of backing plate
7 Recessed section bottom surface of backing plate
8a, 8b Uneven portion
9 Bottom surface of sputtering target
21 Recessed section opening surface
22 Recessed section
23 Protruding section
24 Intermediate layer
24a Intermediate layer provided on interface on backing plate
24b Intermediate layer provided on interface on sputtering target

1. A sputtering target-backing plate assembly in which a sputtering target having a thickness of 2.0 to 15.0 mm is joined to a backing plate,
the backing plate having a recessed section having a depth of 0.5 to 5.0 mm on a plate surface,
the sputtering target being fitted into the recessed section, and
the sputtering target-backing plate assembly having a swaging structure in which an outer-peripheral-side surface of the sputtering target is clamped by a recessed section inner-peripheral-side surface of the backing plate.

2. The sputtering target-backing plate assembly according to claim 1, wherein the outer-peripheral-side surface of the sputtering target has an uneven portion,
the recessed section inner-peripheral-side surface of the backing plate has an uneven portion, and
the uneven portion of the outer-peripheral-side surface and the uneven portion of the recessed section inner-peripheral-side surface are fitted to each other.

3. The sputtering target-backing plate assembly according to claim 1, wherein a recessed section opening surface of the recessed section of the backing plate is smaller than a recessed section bottom surface of the recessed section.

4. The sputtering target-backing plate assembly according to claim 1, wherein a bottom surface of the sputtering target is larger than the recessed section opening surface of the recessed section of the backing plate.

5. The sputtering target-backing plate assembly according to claim 1, wherein a linear expansion coefficient of the backing plate is larger than a linear expansion coefficient of the sputtering target at 200 to 500° C.

6. The sputtering target-backing plate assembly according to claim 1, wherein an intermediate layer having a thickness of 2.5 mm or less is provided on an interface between the sputtering target and the backing plate, and
the intermediate layer is composed of a plate material or powder formed of at least one metal of Ni, Cr, Al, or Cu or an alloy containing at least one of Ni, Cr, Al, or Cu, or a combination of the plate material and the powder.

7. The sputtering target-backing plate assembly according to claim 1, wherein an intermediate layer having a thickness of 10 μm or less is provided on an interface between the sputtering target and the backing plate, and
the intermediate layer is composed of a thin film formed of at least one metal of Ni, Cr, Al, or Cu or an alloy containing at least one of Ni, Cr, Al, or Cu.

8. The sputtering target-backing plate assembly according to claim 1, wherein an intermediate layer having a thickness of 1.0 mm or less is provided on an interface between the sputtering target and the backing plate, and
the intermediate layer is composed of a plate material or powder formed of at least one metal of In or Zn or an alloy containing at least one of In or Zn, or a combination of the plate material and the powder.

9. The sputtering target-backing plate assembly according to claim 1, wherein two or more intermediate layers are provided on an interface between the sputtering target and the backing plate, and
each of the intermediate layers is composed of a plate material having a thickness of 2.5 mm or less or powder and formed of at least one metal of Ni, Cr, Al, or Cu or an alloy containing at least one of Ni, Cr, Al, or Cu, or a combination of the plate material and the powder,
is composed of a thin film having a thickness of 10 μm or less and formed of at least one metal of Ni, Cr, Al, or Cu or an alloy containing at least one of Ni, Cr, Al, or Cu, or
is composed of a plate material having a thickness of 1.0 mm or less or powder and formed of at least one metal of In or Zn or an alloy containing at least one of In or Zn, or a combination of the plate material and the powder.

10. The sputtering target-backing plate assembly according to claim 1, wherein a material of the sputtering target is an Al—Sc alloy, Ru, a Ru alloy, Ir, or an Ir alloy.

11. The sputtering target-backing plate assembly according to claim 1, wherein a material of the sputtering target is a Li-based oxide, a Co-based oxide, a Ti-based oxide, or an Mg-based oxide.

12. The sputtering target-backing plate assembly according to claim 1, wherein a material of the backing plate is Al, an Al alloy, Cu, a Cu alloy, Fe, or an Fe alloy, and the linear expansion coefficient of the backing plate is 30.0×10⁻⁶/° C. or less.

13. The sputtering target-backing plate assembly according to claim 1, wherein a flexural strength of the sputtering target is 500 MPa or less.

14. The sputtering target-backing plate assembly according to claim 1, wherein a planar shape of the recessed section of the backing plate is a circular shape or a rectangular shape including a square shape, and a relationship between a diameter or side length of the recessed section of the backing plate and a diameter or side length of the sputtering target satisfies (Expression 1) to (Expression 5):
D_{TG}>D_{BP} (Expression 1)
D_{BP}=D_{TG}−ΔD×C (Expression 2)
ΔD=D_{BP}×ΔT×CTE_{BP}−D_{TG}×ΔT×CTE_{TG} (Expression 3)
D_{TG}−ΔD×4.0≤D_{BP}≤D_{TG}−ΔD×0.5 (Expression 4)
CTE_{BP}>CTE_{TG} (Expression 5)
where D_{BP}, D_{TG}, ΔD, C, T, ΔT, CTE_{BP}, and CTE_{TG} mean the following:
D_{BP}: the diameter or side length (mm) of the recessed section of the backing plate at room temperature
D_{TG}: the diameter or side length (mm) of the sputtering target at the room temperature
T: a temperature (° C.) at which the backing plate is thermally expanded to fit the sputtering target (where T>the room temperature)
ΔT: T—the room temperature (° C.)
CTE_{BP}: the linear expansion coefficient (1/° C.) of the backing plate at the temperature T
CTE_{TG}: the linear expansion coefficient (1/° C.) of the sputtering target at the temperature T
C: a coefficient (where C=0.5 to 4.0)
ΔD: a difference (mm) in thermal expansion amount between the backing plate and the sputtering target under a condition of rising a temperature from the room temperature to the temperature T.

15. The sputtering target-backing plate assembly according to claim 1, wherein a planar shape of the recessed section of the backing plate is a circular shape or a rectangular shape including a square shape, and a relationship between a diameter or side length of the recessed section of the backing plate and a diameter or side length of the sputtering target satisfies (Expression 6) to (Expression 10):
D_{TG}>D_{BP} (Expression 6)
D_{BP}=D_{TG}−ΔD×C (Expression 7)
ΔD=D_{BP}×ΔT×CTE_{BP}−D_{TG}×ΔT₁×CT₁E_{TG} (Expression 8)
D_{TG}−ΔD×4.0≤D_{BP}≤D_{TG}−ΔD×0.5 (Expression 9)
CTE_{BP}>CT₁E_{TG} (Expression 10)
where D_{BP}, D_{TG}, ΔD, C, T, ΔT, T₁, ΔT₁, CTE_{BP}, and CT₁E_{TG} mean the following:
D_{BP}: the diameter or side length (mm) of the recessed section of the backing plate at room temperature
D_{TG}: the diameter or side length (mm) of the sputtering target at the room temperature
T: a temperature (° C.) of the backing plate at which the backing plate is thermally expanded to fit the sputtering target (where T>the room temperature and T>T₁)
ΔT: T—the room temperature (° C.)
T₁: a temperature (° C.) of the sputtering target at which the backing plate is thermally expanded to fit the sputtering target (where T₁≥the room temperature and T>T₁)
ΔT₁: T₁—the room temperature (° C.)
CTE_{BP}: the linear expansion coefficient (1/° C.) of the backing plate at the temperature T
CT₁E_{TG}: the linear expansion coefficient (1/° C.) of the sputtering target at the temperature T₁
C: a coefficient (where C=0.5 to 4.0)
ΔD: a difference (mm) between a thermal expansion amount of the backing plate under a condition of rising a temperature from the room temperature to the temperature T and a thermal expansion amount of the sputtering target under a condition of rising a temperature from the room temperature to the temperature T₁.

16. The sputtering target-backing plate assembly according to claim 1, wherein the sputtering target is fitted into the backing plate such that the plate surface of the backing plate is exposed to an entire periphery of a target surface of the sputtering target.

17. The sputtering target-backing plate assembly according to claim 1, wherein the target surface of the sputtering target protrudes from the plate surface.

18. A manufacturing method for a sputtering target-backing plate assembly, the manufacturing method comprising:
a step 1 of preparing a sputtering target having a thickness of 2.0 to 15.0 mm and a backing plate;
a step 2 of forming a recessed section having a depth of 0.5 to 5.0 mm in a plate surface of the backing plate;
a step 3 of heating the backing plate to thermally expand the recessed section;
a step 4 of fitting the sputtering target into the thermally expanded recessed section; and
a step 5 of cooling the backing plate to form a swaging structure in which an outer-peripheral-side surface of the sputtering target is clamped by a recessed section inner-peripheral-side surface of the backing plate.

19. The manufacturing method for a sputtering target-backing plate assembly according to claim 18, further comprising, between the step 2 and the step 3 or between the step 3 and the step 4, a step 6 of filling or coating the recessed section with a material of an intermediate layer.

20. The manufacturing method for a sputtering target-backing plate assembly according to claim 18, further comprising, between the step 4 and the step 5, a step 7 of pressing the sputtering target to diffuse a bottom surface of the sputtering target and a bottom surface of the recessed section of the backing plate.

21. The manufacturing method for a sputtering target-backing plate assembly according to claim 18, wherein at least the step 3, the step 4, and the step 5 are performed by using at least one of a hot press (HP) sintering method, a hot isostatic pressing (HIP) sintering method, a spark plasma sintering (SPS) method, or a heating method using a hot plate.

22. The manufacturing method for a sputtering target-backing plate assembly according to claim 20, wherein the step 7 is performed by using at least one of a hot press (HP) sintering method, a hot isostatic pressing (HIP) sintering method, or a spark plasma sintering (SPS) method.

23. The manufacturing method for a sputtering target-backing plate assembly according to claim 20, wherein in the step 7, a reduced-pressure atmosphere of 10 Pa or less or an atmosphere having an oxygen concentration of 1000 ppm or less is set, a heating temperature is set to 100 to 1000° C., and a pressing force is set to a range of 0 Pa or more and 80 MPa or less.

24. The manufacturing method for a sputtering target-backing plate assembly according to claim 18, wherein after the step 5, a pair of a step of pressing or heating and pressing and a step of cooling is performed once or repeatedly twice or more.

25. A recovery method for a sputtering target, the recovery method comprising:
a step A of heating the sputtering target-backing plate assembly according to claim 1 to thermally expand the recessed section opening surface of the backing plate until making the recessed section opening surface larger than the bottom surface of the sputtering target; and
a step B of detaching the sputtering target from the backing plate to recover the sputtering target from the sputtering target-backing plate assembly.
